(19) United States
(12) Patent Application Publication
(10) Pub. No.: US 2024/0348783 A1
(43) Pub. Date: Oct. 17, 2024

(54) METHODS AND APPARATUS FOR APPROXIMATING A CUMULATIVE DISTRIBUTION FUNCTION FOR USE IN ENTROPY CODING OR DECODING DATA

(71) Applicant: HUAWEI TECHNOLOGIES CO., LTD., Shenzhen (CN)

(72) Inventors: Maxim Borisovitch Sychev, Moscow (RU); Andrey Gennadevich Soroka, Munich (DE)

(21) Appl. No.: 18/750,638

(22) Filed: Jun. 21, 2024

Related U.S. Application Data
(63) Continuation of application No. PCT/RU2021/000590, filed on Dec. 23, 2021.

(51) Int. Cl. H04N 19/13; H04N 19/149; H04N 19/91

(52) U.S. Cl. CPC H04N 19/13; H04N 19/149; H04N 19/91

(57) ABSTRACT

Methods and apparatuses are provided to approximate a cumulative distribution function (CDF) interval-wise with second order polynomials, while posing constraints on the polynomials within the intervals and/or on the boundary between the intervals. In this manner, a CDF approximation is obtained, which may be used in a variety of applications including entropy encoding and decoding of any source data. The constraints correspond to the characteristics of the CDF to be approximated.

### CROSS-REFERENCE TO RELATED APPLICATIONS

This application is a continuation of International Application No. PCT/RU2021/000590, filed on Dec. 23, 2021, the disclosure of which is hereby incorporated by reference in its entirety.

### FIELD

Embodiments of the present disclosure relate to obtaining a cumulative distribution function, for example, for use in entropy encoding and decoding, for example, for picture or video coding.

### BACKGROUND

Hybrid image and video codecs have been used for decades to compress image and video data. In such codecs, a signal is typically encoded block-wisely by predicting a block and by further coding only the difference between the original bock and its prediction. In particular, such coding may include transformation, quantization and generating the bitstream, usually including some entropy coding. Typically, the three components of hybrid coding methods—transformation, quantization, and entropy coding—are separately optimized. Modern video compression standards like High-Efficiency Video Coding (HEVC), Versatile Video Coding (VVC) and Essential Video Coding (EVC) also use a transformed representation to code residual signals after prediction.

Recently, neural network architectures have been applied to image and/or video coding. In general, these neural network (NN) based approaches can be applied in various different ways to the image and video coding. For example, some end-to-end optimized image or video coding frameworks have been discussed. Moreover, deep learning has been used to determine or optimize some parts of the end-to-end coding framework such as selection or compression of prediction parameters or the like. Besides, some neural network based approaches have also been discussed for usage in hybrid image and video coding frameworks, e.g. for implementation as a trained deep learning model for intra or inter prediction in image or video coding.

The end-to-end optimized image or video coding applications discussed above have in common that they produce some feature map data, which is to be conveyed between encoder and decoder.

Neural networks are machine learning models that employ one or more layers of nonlinear units based on which they can predict an output for a received input. Some neural networks include one or more hidden layers in addition to an output layer. A corresponding feature map may be provided as an output of each hidden layer. Such corresponding feature map of each hidden layer may be used as an input to a subsequent layer in the network, i.e., a subsequent hidden layer or the output layer. Each layer of the network generates an output from a received input in accordance with current values of a respective set of parameters. In a neural network that is split between devices, e.g. between encoder and decoder, a device and a cloud or between different devices, a feature map at the output of the place of splitting (e.g. a first device) is compressed and transmitted to the remaining layers of the neural network (e.g. to a second device).

Further improvement of encoding and decoding using trained network architectures may be desirable.

### SUMMARY

The embodiments of the present disclosure provide apparatuses and methods for obtaining a cumulative distribution function for entropy encoding and decoding.

According to an embodiment a method is provided for entropy encoding data into a bitstream, comprising: obtaining a cumulative distribution function, CDF, for at least one interval out of a plurality of intervals, wherein the CDF is obtained based on a function defined in the at least one interval by parameters of a second order polynomial, and said second order polynomial fulfills a set of conditions; entropy encoding said data applying a probability model based on the obtained CDF in the at least one interval.

Obtaining a CDF based on a set of parameters describing second order polynomials provides a reliable and reproducible method to obtain an estimate for a probability model used in entropy encoding. The function represents an approximation of a CDF using second order polynomials, while the conditions enable a better adaption of the approximation to some inherent characteristics of the CDF.

In an exemplary implementation, the set of conditions includes one or more of: the second order polynomial within the at least one interval and a polynomial in an adjoining interval provide a monotonically non-decreasing function, the second order polynomial has a non-negative derivative within the at least one interval.

These conditions represent particular properties of the approximation provided by the function, i.e. monotonicity, curvature and the like. They reflect features of a CDF and thus lead to an approximation suitable for use as CDF in the entropy encoding.

For example, the function defined by the parameters specifies a predefined CDF with a predefined mean value and a predefined standard deviation.

Provision of a predefined CDF has the advantage that such predefined CDF may be efficiently stored or derived where necessary, while possible further CDFs can be obtained based on the predefined CDF.

In an exemplary implementation, the CDF is obtained by shifting at least one argument of the function.

Shifting the argument allows using the approximation provided by the function for obtaining additional CDF having, for example, a mean that is different from a predefined mean used in the obtaining of the function. Only the parameter of the predefined CDF need to be stored or derived.

For example, the CDF is obtained by scaling at least one argument of the function.

Scaling the argument allows using the approximation provided by the function for obtaining additional CDF having, for example, a standard deviation that is different from a predefined standard deviation used in the obtaining of the function. Only the parameter of the predefined CDF need to be stored or derived.

In an exemplary implementation, the entropy encoding is an arithmetic encoding.

Arithmetic encoding is an efficient entropy coding which may contribute to reduction of the rate. It may advantageously employ a CDF approximation obtained as described above.

For example, the function within one or more intervals out of the plurality of intervals is defined by a linear polynomial.

Using a linear approximation, for example, in regions having a nearly constant slope, may reduce the number of parameters that are provided to specify the approximating function.

In an exemplary implementation, the function within a last interval out of the plurality of intervals is defined by a linear polynomial.

In the last interval, a CDF approximates the asymptotic value of 1. Thus, a linear approximation reduces the number of parameters while not remarkably reducing the accuracy of the approximation.

For example, the function is approximating a predefined CDF having a predefined mean and a predefined standard deviation, the function is point-symmetric with respect to the predefined mean and the function is defined in intervals including values higher than said predefined mean.

Exploiting the symmetry of the CDF reduces the number of intervals and thus the number of parameters that are provided to specify the approximating function. This results in lower requirements regarding storage for the parameters.

In an exemplary implementation, a look-up table, LUT, provides the parameters for each interval.

A look-up table provides an efficient implementation for a set of parameters.

For example, the obtained CDF represents a CDF of a Gaussian distribution.

The method is readily applied to a Gaussian CDF, which is commonly used in entropy encoding.

In an exemplary implementation, the parameters are in a fixed-point representation having a predetermined precision.

Such a fixed-point representation together with a predetermined precision allows to provide a same precision and a same fixed-point representation leading to the same values on different types of platforms (hardware and/or software). The same values for the CDF result in a same mapping of symbols and ranges at the encoder and the decoder, which then leads to compatibility and ensures a synchronized entropy encoding and decoding (i.e. deterministic entropy coding across different software and hardware platforms).

For example, in the obtaining of the CDF intermediate results are adapted to the predetermined precision according to a set of rules.

Adapting the intermediate results to the predetermined precision further ensures compatibility between different platforms and a synchronized entropy encoding and decoding.

In an exemplary implementation, for a value x=s−μ−0.5 within the at least one interval, where s represents the symbol to be encoded and y is the mean of the CDF, the CDF is obtained for x smaller than zero by CDF(x)=M−(aᵢv²+bᵢv+cᵢ)+s, wherein aᵢ, bᵢ and cᵢ are the parameters of a second order polynomial within the at least one interval, the parameter

$$v = \frac{- x}{{σ}_{left} + ϵ}$$

scales the value x by the standard deviation σ_{left} of the CDF for x smaller than zero and a small predetermined parameter ϵ>0, and the multiplication factor M, which is related to the predetermined precision 1/M, is defined by M=total−sₘₐₓ−1, where total is related to the number of bits used in entropy encoding and sₘₐₓ is the maximal value of a symbol to be encoded; and the CDF is obtained for x greater than zero by CDF(x)=aᵢv²+bᵢv+cᵢ+s, wherein aᵢ, bᵢ and cᵢ are the parameters of a second order polynomial within the at least one interval, the parameter

$$v = \frac{x}{{σ}_{right} + ϵ}$$

scales the value x by the standard deviation σ_{left} of the CDF for x greater than zero and a small predetermined parameter ϵ>0.

Such a combination of shifting and scaling provides an efficient implementation for obtaining a CDF from a subset of parameters aᵢ, bᵢ, cᵢ in an interval i.

According to an embodiment, a method is provided for entropy decoding data from a bitstream, comprising: obtaining a cumulative distribution function, CDF, for at least one interval out of a plurality of predetermined intervals, wherein the CDF is obtained based on a function defined in the at least one interval by parameters of a second order polynomial, and said second order polynomial fulfills a set of conditions; entropy decoding said data applying a probability model based on the obtained CDF in the at least one interval.

Obtaining a CDF based on a set of parameters describing second order polynomials provides a reliable and reproducible method to obtain an estimate for a probability model used in entropy encoding. The function represents an approximation of a CDF using second order polynomials, while the conditions enable a better adaption of the approximation to some inherent characteristics of the CDF.

In an exemplary implementation, the set of conditions includes one or more of: the second order polynomial within the at least one interval and a polynomial in an adjoining interval provide a monotonically non-decreasing function, the second order polynomial has a non-negative derivative within the at least one interval.

These conditions represent particular properties of the approximation provided by the function, i.e. monotonicity, curvature and the like. They reflect features of a CDF and thus lead to an approximation suitable for use as CDF in the entropy encoding.

For example, the function defined by the parameters specifies a predefined CDF with a predefined mean value and a predefined standard deviation.

Provision of a predefined CDF has the advantage that such predefined CDF may be efficiently stored or derived where necessary, while possible further CDFs can be obtained based on the predefined CDF.

In an exemplary implementation, the CDF is obtained by shifting at least one argument of the function.

Shifting the argument allows using the approximation provided by the function for obtaining additional CDF having, for example, a mean that is different from a predefined mean used in the obtaining of the function. Only the parameter of the predefined CDF need to be stored or derived.

For example, the CDF is obtained by scaling at least one argument of the function.

Scaling the argument allows using the approximation provided by the function for obtaining additional CDF having, for example, a standard deviation that is different from a predefined standard deviation used in the obtaining of the function. Only the parameter of the predefined CDF need to be stored or derived.

In an exemplary implementation, the entropy decoding is an arithmetic decoding.

Arithmetic decoding is an efficient entropy coding which may contribute to reduction of the rate. It may advantageously employ a CDF approximation obtained as described above.

For example, the function within one or more intervals out of the plurality of intervals is defined by a linear polynomial.

Using a linear approximation, for example, in regions having a nearly constant slope, may reduce the number of parameters that are provided to specify the approximating function.

In an exemplary implementation, the function within a last interval out of the plurality of intervals is defined by a linear polynomial.

In the last interval, a CDF approximates the asymptotic value of 1. Thus, a linear approximation reduces the number of parameters while not remarkably reducing the accuracy of the approximation.

For example, the function is approximating a predefined CDF having a predefined mean and a predefined standard deviation, the function is point-symmetric with respect to the predefined mean and the function is defined in intervals including values higher than said predefined mean.

Exploiting the symmetry of the CDF reduces the number of intervals and thus the number of parameters that are provided to specify the approximating function. This results in lower requirements regarding storage for the parameters.

In an exemplary implementation, a look-up table, LUT, provides the parameters for each interval.

A look-up table provides an efficient implementation for a set of parameters.

For example, the obtained CDF represents a CDF of a Gaussian distribution.

The method is readily applied to a Gaussian CDF, which is commonly used in entropy decoding.

In an exemplary implementation, the parameters are in a fixed-point representation having a predetermined precision.

Such a fixed-point representation together with a predetermined precision allows to provide a same precision and a same fixed-point representation leading to the same values on different types of platforms (hardware and/or software). The same values for the CDF result in a same mapping of symbols and ranges at the encoder and the decoder, which then leads to compatibility and ensures a synchronized entropy encoding and decoding (i.e. deterministic entropy coding across different software and hardware platforms).

For example, in the obtaining of the CDF intermediate results are adapted to the predetermined precision according to a set of rules.

Adapting the intermediate results to the predetermined precision further ensures compatibility between different platforms and a synchronized entropy encoding and decoding.

In an exemplary implementation, for a value x=s−μ−0.5 within the at least one interval, where s represents the symbol to be encoded and y is the mean of the CDF, the CDF is obtained for x smaller than zero by CDF(x)=M−(aᵢv²+bᵢv+cᵢ)+s, wherein aᵢ, bᵢ and cᵢ are the parameters of a second order polynomial within the at least one interval, the parameter

$$v = \frac{- x}{{σ}_{left} + ϵ}$$

scales the value x by the standard deviation σ_{left} of the CDF for x smaller than zero and a small predetermined parameter ϵ>0, and the multiplication factor M, which is related to the predetermined precision 1/M, is defined by M=total−sₘₐₓ−1, where total is related to the number of bits used in entropy encoding and sₘₐₓ is the maximal value of a symbol to be encoded; and the CDF is obtained for x greater than zero by CDF(x)=aᵢv²+bᵢv+cᵢ+s, wherein aᵢ, bᵢ and cᵢ are the parameters of a second order polynomial within the at least one interval, the parameter

$$v = \frac{x}{{σ}_{right} + ϵ}$$

scales the value x by the standard deviation σ_{left} of the CDF for x greater than zero and a small predetermined parameter ϵ>0.

Such a combination of shifting and scaling provides an efficient implementation for obtaining a CDF from a subset of parameters aᵢ, bᵢ, cᵢ in an interval i.

According to an embodiment, a method is provided for obtaining a set of parameters specifying a cumulative distribution function, CDF, for entropy encoding, the method comprising: for an interval within a plurality of predetermined intervals: obtaining a subset of said set of parameters defining a second order polynomial within said interval, the second order polynomial approximating the CDF, wherein said polynomial fulfills a set of conditions.

Obtaining a set of parameters describing second order polynomials enables a reliable and reproducible method to obtain an approximation of a CDF, while the conditions enable a better adaption of the approximation to some inherent characteristics of the CDF.

In an exemplary implementation, the set of conditions includes one or more of: the second order polynomial and a polynomial within an adjoining interval provide a monotonically non-decreasing function, the second order polynomial has a non-negative derivative within the respective interval.

These conditions represent particular properties of the CDF approximated by the function, i.e. monotonicity, curvature and the like. They reflect features of a CDF and thus lead to an approximation suitable for use as CDF in the entropy encoding.

For example, the function defined by the parameters specifies a predefined CDF based on a predefined mean value and a predefined standard deviation.

Using a predefined CDF has the advantage that such predefined CDF may be efficiently stored or derived where necessary, while possible further CDFs can be obtained based on the predefined CDF.

In an exemplary implementation, the function within one or more intervals out of the plurality of intervals is defined by a linear polynomial.

Using a linear approximation, for example, in regions having a nearly constant slope, may reduce the number of parameters that are provided to specify the approximating function.

For example, the function within a last interval out of the plurality of intervals is defined by a linear polynomial.

In the last interval, a CDF approximates the asymptotic value of 1. Thus, a linear approximation reduces the number of parameters while not remarkably reducing the accuracy of the approximation.

In an exemplary implementation, the function is approximating a predefined CDF having a predefined mean and a predefined standard deviation, the function is point-symmetric with respect to the predefined mean and the function is defined in intervals including values higher than said predefined mean.

Exploiting the symmetry of the CDF reduces the number of intervals and thus the number of parameters that are provided to specify the approximating function. This results in lower requirements regarding storage for the parameters.

For example, the parameters for each interval are stored in a look-up table, LUT.

A look-up table provides an efficient implementation for a set of parameters.

In an exemplary implementation, the CDF represents a CDF of a Gaussian distribution.

The method is readily applied to a Gaussian CDF, which is commonly used in entropy encoding.

For example, the parameters are in a fixed-point representation having a predetermined precision.

Such a fixed-point representation together with a predetermined precision allows to provide a same precision and a same fixed-point representation leading to the same values on different types of platforms (hardware and/or software). The same values for the CDF result in a same mapping of symbols and ranges at the encoder and the decoder, which then leads to compatibility and ensures a synchronized entropy encoding and decoding (i.e. deterministic entropy coding across different software and hardware platforms).

In an exemplary implementation, in the obtaining a cost function is optimized, the cost function including a difference between the second order polynomial and the CDF.

Optimizing a cost function provides an efficient implementation for obtaining a subset of parameters within an interval.

For example, the cost function includes a penalty, which enhances the difference between the second order polynomial and the CDF at the boundaries of said interval.

Such a cost function increases the influence of the regions close to the interval boundaries. This allows for an efficient treatment of the conditions to be fulfilled at the interval boundaries.

In an exemplary implementation, the cost function includes a penalty, which is added when a vertex of a parabola defined by the second order polynomial is within said interval or left of said interval.

Such a penalty ensures that the function is monotonically increasing within the interval and thus, respects the properties of the CDF that is approximated.

In an exemplary implementation, a computer program stored on a non-transitory medium and including code instructions, which, when executed on one or more processors, cause the one or more processors to execute steps of the method according to any of the methods described above.

According to an embodiment, an apparatus is provided for entropy encoding data into a bitstream, comprising: processing circuitry configured to: obtain a cumulative distribution function, CDF, for at least one interval out of a plurality of predetermined intervals, wherein the CDF is obtained based on a function defined in the at least one interval by parameters of a second order polynomial, and said second order polynomial fulfills a set of conditions; entropy encode said data applying a probability model based on the obtained CDF in the at least one interval.

According to an embodiment, an apparatus is provided for entropy decoding data from a bitstream, comprising: processing circuitry configured to: obtain a cumulative distribution function, CDF, for at least one interval out of a plurality of predetermined intervals, wherein the CDF is obtained based on a function defined in the at least one interval by parameters of a second order polynomial, and said second order polynomial fulfills a set of conditions; entropy decode said data applying a probability model based on the obtained CDF in the at least one interval.

According to an embodiment, an apparatus is provided for obtaining a set of parameters specifying a cumulative distribution function, CDF, for entropy encoding, the apparatus comprising processing circuitry configured to: for an interval within a plurality of predetermined intervals: obtain a subset of said set of parameters defining a second order polynomial within said interval, the second order polynomial approximating the CDF, wherein said polynomial fulfills a set conditions.

According to an embodiment, a computer readable recording medium is provided for storing a bitstream generated by an entropy encoding method according to any one of the embodiments and/or implementations described herein or an apparatus for entropy encoding according to according to any one of the embodiments and/or implementations described herein. The computer readable recording medium may also be or referred to as computer readable storage medium and can be, e.g., a non-transitory computer readable recording medium, e.g. a non-transitory computer readable storage medium.

The apparatuses provide the advantages of the methods described above.

Embodiments of the present disclosure can be implemented in hardware (HW) and/or software (SW) or in any combination thereof. Moreover, HW-based implementations may be combined with SW-based implementations.

Embodiments and implementations described herein allow to provide, for example, a low-complexity, fixed-point approximation of a normal cumulative distribution function.

Embodiments and implementations described herein may be used for coding still pictures, video pictures and audio signals (e.g. multi-channel audio signals), respectively entropy coding and decoding data related to still pictures, video pictures and audio signals but are not limited to those. For example, embodiments and implementations described herein may also be used (in an identical or corresponding manner) for obtaining an activation function of or for a neural network (instead of obtaining a CDF for entropy coding and/or decoding), wherein the activation function is obtained based on a function defined in the at least one interval by parameters of a second order polynomial and the second order polynomial fulfills a set of conditions. The neural network may be used, for example, for coding or compressing/decompressing still pictures, video pictures and audio signals (e.g. multi-channel audio signals), or for processing still pictures, video pictures or audio signals in general (for example for classification, denoising or other purposes), or the neural network maybe used for encryption of data or other purposes.

Details of one or more embodiments are set forth in the accompanying drawings and the description below. Other features, objects, and advantages will be apparent from the description, drawings, and claims.

### BRIEF DESCRIPTION OF THE DRAWINGS

In the following, embodiments of the present disclosure are described in more detail with reference to the attached figures and drawings, in which:

FIG. 1 is a schematic drawing illustrating encoding of a message using an alphabet with two symbols with an arithmetic coding according to some embodiments.

FIG. 2 is a schematic drawing of a first step of an arithmetic (range) coding of a message using an alphabet with eight symbols according to some embodiments.

FIG. 3 is a schematic drawing of a second step of the arithmetic (range) coding of the message using the alphabet with eight symbols according to some embodiments.

FIG. 4 is a schematic drawing of a third step of the arithmetic (range) coding of the message using the alphabet with eight symbols according to some embodiments.

FIG. 5 is a schematic drawing of a fourth step of the arithmetic (range) coding of the message using the alphabet with eight symbols according to some embodiments.

FIG. 6 is a schematic drawing of a final step of the arithmetic (range) coding of the message using the alphabet with eight symbols according to some embodiments.

FIG. 7a-d are schematic drawings illustrating the values of a minimum and a maximum of the range during the coding steps, expressed as binary numbers according to some embodiments.

FIG. 8 is a schematic drawing illustrating an exemplary arithmetic decoding according to some embodiments.

FIG. 9 shows exemplarily CDFs for normal distributions having different mean values and standard deviations according to some embodiments.

FIG. 10 illustrates an exemplary approximation of the error function by second order polynomials according to some embodiments.

FIG. 11 is a schematic drawing obtaining a second order polynomial within an interval from a look-up table to approximate a CDF according to some embodiments.

FIG. 12a-b are schematic drawings illustrating conditions fulfilled by second order polynomials approximating the CDF according to some embodiments.

FIG. 13 illustrates exemplarily the floating-point format and the fixed-point format according to some embodiments.

FIG. 14a-b are flowcharts for an exemplary implementation to obtain a set of parameters, which define a second order polynomial according to some embodiments.

FIG. 15 is a schematic drawing of an entropy encoder and decoder using a CDF according to some embodiments.

FIG. 16 is a schematic drawing illustrating channels processed by layers of a neural network according to some embodiments.

FIG. 17 is a schematic drawing illustrating an autoencoder type of a neural network according to some embodiments.

FIG. 18a is a schematic drawing illustrating an exemplary network architecture for encoder and decoder side including a hyperprior model according to some embodiments.

FIG. 18b is a schematic drawing illustrating a general network architecture for encoder side including a hyperprior model according to some embodiments.

FIG. 18c is a schematic drawing illustrating a general network architecture for decoder side including a hyperprior model according to some embodiments.

FIG. 19 is a schematic drawing illustrating an exemplary network architecture for encoder and decoder side including a hyperprior model according to some embodiments.

FIG. 20 is a block diagram illustrating employing the arithmetic encoding of some embodiments in a picture encoding according to some embodiments.

FIG. 21 is a block diagram illustrating employing the arithmetic encoding of some embodiments in a picture decoding according to some embodiments.

FIG. 22 is a block diagram showing an example of a video coding system configured to implement embodiments of the present disclosure according to some embodiments.

FIG. 23 is a block diagram showing another example of a video coding system configured to implement embodiments of the present disclosure according to some embodiments.

FIG. 24 is a block diagram illustrating an example of an encoding apparatus or a decoding apparatus according to some embodiments.

FIG. 25 is a block diagram illustrating another example of an encoding apparatus or a decoding apparatus according to some embodiments.

### DETAILED DESCRIPTION

In the following description, reference is made to the accompanying figures, which form part of the disclosure, and which show, by way of illustration, embodiments of the present disclosure or aspects in which embodiments of the present disclosure may be used. It is understood that embodiments of the present disclosure may be used in other aspects and comprise structural or logical changes not depicted in the figures. The following detailed description, therefore, is not to be taken in a limiting sense, and the scope of the present disclosure is defined by the appended claims.

For instance, it is understood that a disclosure in connection with a described method may also hold true for a corresponding device or system configured to perform the method and vice versa. For example, if one or a plurality of method steps is described, a corresponding device may include one or a plurality of units, e.g. functional units, to perform the described one or plurality of method steps (e.g. one unit performing the one or plurality of steps, or a plurality of units each performing one or more of the plurality of steps), even if such one or more units are not explicitly described or illustrated in the figures. On the other hand, for example, if an apparatus is described based on one or a plurality of units, e.g. functional units, a corresponding method may include one step to perform the functionality of the one or plurality of units (e.g. one step performing the functionality of the one or plurality of units, or a plurality of steps each performing the functionality of one or more of the plurality of units), even if such one or plurality of steps are not explicitly described or illustrated in the figures. Further, it is understood that the features of the various exemplary embodiments and/or aspects described herein may be combined with each other, unless specifically noted otherwise.

Video coding typically refers to the processing of a sequence of pictures, which form the video or video sequence. Instead of the term picture the terms frame or image may be used as synonyms in the field of video coding. Video coding comprises two parts, video encoding and video decoding. Video encoding is performed at the source side, typically comprising processing (e.g. by compression) the original video pictures to reduce the amount of data required for representing the video pictures (for more efficient storage and/or transmission). Video decoding is performed at the destination side and typically comprises the inverse processing compared to the encoder to reconstruct the video pictures. Embodiments referring to “coding” of video pictures (or pictures in general, as will be explained later) shall be understood to relate to both, “encoding” and “decoding” of video pictures. The combination of the encoding part and the decoding part is also referred to as CODEC (COding and DECoding).

In case of lossless video coding, the original video pictures can be reconstructed, i.e. the reconstructed video pictures have the same quality as the original video pictures (assuming no transmission errors or other data loss during storage or transmission). In case of lossy video coding, further compression, e.g. by quantization, is performed, to reduce the amount of data representing the video pictures, which cannot be completely reconstructed at the decoder, i.e. the quality of the reconstructed video pictures is lower or worse compared to the quality of the original video pictures.

In the following, an overview over some of the used technical terms and framework within which the embodiments of the present disclosure may be employed is provided.

### Arithmetic Encoding

Entropy coding is typically employed as a lossless coding. Arithmetic coding is a class of entropy coding, which encodes a message as a binary real number within an interval (a range) that represents the message. Herein, the term message refers to a sequence of symbols. Symbols are selected out of a predefined alphabet of symbols. For example, an alphabet may consist of two values 0 and 1. A message using such alphabet is then a sequence of bits. The symbols (0 and 1) may occur in the message with mutually different frequency. In other words, the symbol probability may be non-uniform. In fact, the less uniform the distribution, the higher is the achievable compression by an entropy code in general and arithmetic code in particular. Arithmetic coding makes use of an a priori known probability model specifying the symbol probability for each symbol of the alphabet.

An alphabet does not need to be binary. Rather, the alphabet may consist e.g. of 8 values 0 to 7. In general, any alphabet with any size may be used. Typically, the alphabet is given by the value range of the coded data.

The interval representing the message is obtained by splitting an initial range according to probabilities of the alphabet symbols, with which the message is coded.

For example, let the current interval be the initial interval [0, 1) at the beginning. For each symbol of the message, the following two steps are performed:
1) subdividing the current interval into subintervals, one for each possible alphabet symbol. The size of a symbol's subinterval is proportional to the estimated probability that the symbol will be the next symbol in the message according to the probability model (of the symbol source).
2) selecting the subinterval corresponding to the symbol that actually occurs next in the message, and making the selected subinterval the new current interval.

As a third step, enough bits are output to distinguish the current interval from all other possible intervals. This step may be performed already during the encoding in steps 1 and 2, or after the encoding of the entire message. The length of the interval obtained after repeating steps 1) and 2) for all symbols of the message is clearly equal to the product of the probabilities of the individual symbols, which is also the probability of the particular sequence of symbols in the message.

In theory, an arithmetic coder recursively splits the interval from 0 to 1 to encode the message of any length, resulting in smaller and smaller intervals. In practice, systems are limited by a finite bit depth—only discrete values are representable. Thus, the smaller the interval, the higher precision arithmetic would be necessary. Moreover, no output would be produced until the entire message has been read. A solution to both of these problems may be to output some bits as soon as they are known, and then to double the length of the current interval for each output bit so that it reflects only the (still) unknown part of the interval. In practice, the arithmetic can be done by storing the current interval in sufficiently long integers rather than in floating point or exact rational numbers.

A variation of the arithmetic coder improved for a practical use is referred to as a range coder, which does not use the interval [0,1), but a finite range of integers, e.g. from 0 to 255. This range is split according to probabilities of the alphabet symbols. The range may be renormalized if the remaining range becomes too small in order to describe all alphabet symbols according to their probabilities.

Regarding the terminology employed herein, a current interval is given by its minimum value (denoted as LOW) and its maximum value (denoted as HIGH). The length of the interval is denoted as RANGE. In general, HIGH=LOW+RANGE, and the RANGE is expressed in number of the minimum sized (distinguishable) subintervals. The minimum range for encoding a symbol is BOTTOM. This minimum range ensures that the least likely symbols still have a valid range of at least 1. In other words, BOTTOM is a design parameter, which may be determined based on the alphabet symbols and their probability, to ensure that the range can still be divided into distinguishable intervals corresponding to all alphabet symbols.

The HIGH position indicates how many bits are required to cover the initial maximum range. The BOTTOM position indicates how many bits are required to cover the minimum range for encoding another symbol. The amount of bits between the HIGH position and the predetermined TOP position corresponds to minimum portion of bits, which can be streamed (inserted) into the bitstream and which become coded bits.

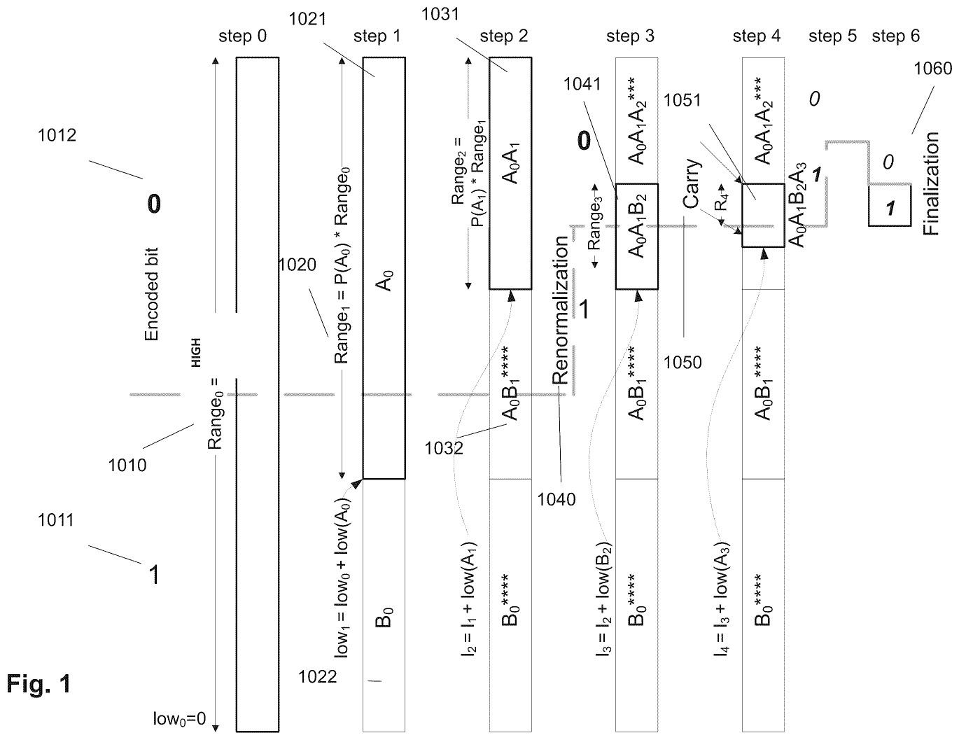

FIG. 1 schematically illustrates an exemplary procedure of arithmetic coding. A message to be coded is provided in an alphabet with two possible symbols A and B. The symbols of the alphabet {A, B} have the probabilities P(A)=2/3 and P(B)=1/3. The message to be encoded reads AABA.

Step 0 shows the initial interval with the length Range₀ 1010 corresponding here to HIGH, since initially, LOW=0 (in step 0 low₀=0). In the lower half of Range₀ the leading bit of the binary representations of the numbers within Range₀ is 1 1011, whereas in the upper half of Range₀ the leading bit is 0 1012. In other words, a current interval in any of the steps, which falls into the upper half of the initial range, will have the first leading bit 0, whereas the current interval, which falls into the lower half of the initial range, will have the first leading bit 1. Assuming here e.g. that any number (code value) within the initial range is representable by 8 bits, the range is from 0 to 255, so that HIGH=255.

In step 1, Range₀ is divided according to the probabilities and to encode the first symbol A₀. In this example, the initial interval is split into two intervals with sizes ⅓ 1022 (corresponding to symbol B₀) and ⅔ 1021(corresponding to symbol A₀) of the total range size. Dividing according to the probabilities means that the initial interval is split into a number of subintervals equal to the number of symbols in the alphabet (here two symbols A and B) and the sizes of the intervals are proportional to the respective probabilities of the symbols represented by the intervals. The upper subinterval Range₁=P(A₀)*Range₀, corresponding to the message symbol A₀ is then selected as current interval for the next step.

In step 2, the range of the symbol A₀, Range₁ 1020, is divided according to the probabilities. The next message symbol is A. As the remaining Range₂=P(A₁)*Range₁, which describes the message A₀A₁ 1031, lies completely within the upper half of the Range₀ to be encoded with bit 0, adding the bit 0 to the encoded bitstream is performed. In this particular, exemplary implementation, a bit is added into the bitstream as soon as it can be, and a renormalization 1040 is performed to double the resolution. The current maximum range is now the upper half of the initial range of step 0. The upper half of this current maximum range is assigned to bit 0 and lower half of the current maximum range is assigned to bit 1.

The message A₀A₁B₂ 1041 in step 3 still cannot be encoded unambiguously, as Range₃ overlaps with a bit 1 (the corresponding bottom half of the current maximum range) as well as with a bit 0 (the corresponding top half of the current maximum range), thus a carrying 1050 is performed. Nothing is streamed (no bit is included into the bitstream). Range₃ is divided in step 4 according to the probabilities of the symbols of the alphabet.

Now the message to be encoded reads A₀A₁B₂A₃ 1051. Range₄ still overlaps with both possible bits and as there is no further symbol to be encoded, in step 5 and 6 a finalization 1060 is performed. This includes several renormalizations, which are performed to create the unambiguous code 0011 for the message AABA.

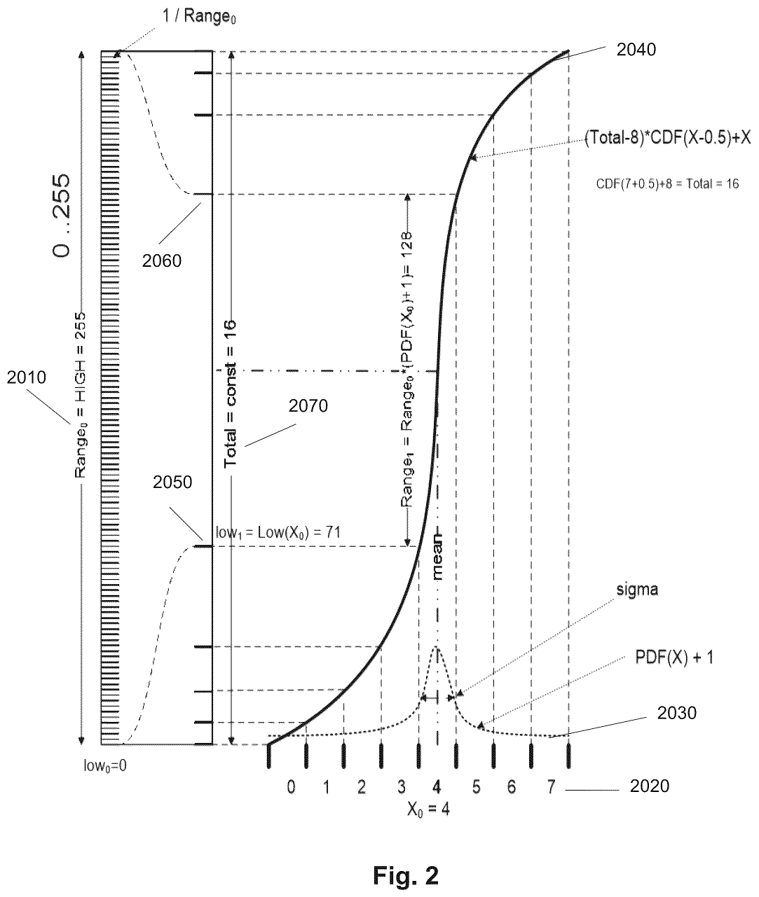

FIGS. 2 to 7 show an example for a range encoder in which the eight symbols of the alphabet 2020 {0, 1, 2, 3, 4, 5, 6, 7} have probabilities according to a probability density function PDF 2030 for a standard normal distribution. The symbols are mapped onto the range by the cumulative distribution function CDF 2040. The message to be encoded reads 4420. The maximum starting range HIGH for encoding is represented in this example by 8 bits corresponding to a code value of 255. The minimum range for encoding a symbol is BOTTOM=16 in this example. This minimum range ensures that even the least likely symbols “0” and “7” still have a valid range of at least 1 when the cumulative distribution function is applied. For example, the normal distribution results in the following number of the smallest intervals per the eight symbols: 1, 1, 2, 3, 4, 2, 2, 1.

FIG. 2 illustrates that the initial range 2010 Range₀=HIGH=255=1111 1111.b, where .b is the binary representation of a number, is mapped onto the symbols 2020 of the alphabet according to the Gaussian probability density function PDF 2030. The partitioning of Range₀ is obtained from the cumulative distribution function CDF 2040. This implies that the first symbol of the message to be encoded, namely “4”, is represented by any of the code values in the interval with the lower endpoint 2050 Low₁=71=0100 0111.b and the excluded upper endpoint 2060 Low₁+Range₁=199=1100 0111.b, which corresponds to a Range₁=128. The total=const=16 2070 implies a working precision of 1/16. This indicates that the subrange which is assigned to the least likely symbol is 1/total= 1/16 of the current range. The total 2070 is determined by the cumulative distribution function.

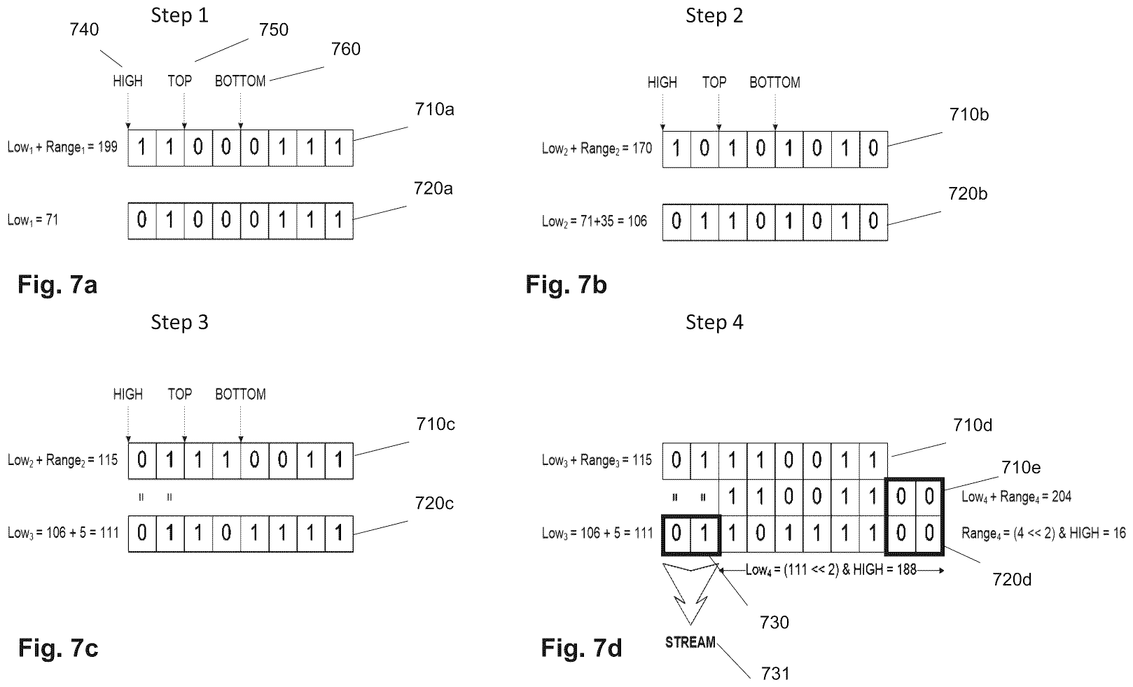

The binary representation of this interval is shown in FIG. 7a together with indications of the HIGH, TOP and BOTTOM positions. The HIGH position 740 indicates how many bits are required to cover the initial maximum range (in this case 8). The BOTTOM position 760 indicates how many bits are required to cover the minimum range for encoding another symbol (in this case 4). The amount of bits between the HIGH position 740 and the predetermined TOP position 750 corresponds to a minimum portion of bits, which can be streamed (inserted) into the bitstream and which then become coded bits. For arithmetic coding described above with reference to FIG. 1, there is only one bit between the HIGH position 740 and the TOP position 750. For range coding of this example, there are two bits between the HIGH position 740 and the TOP position 750. In FIG. 7a (as well as FIGS. 7b-7d) the minimum of the interval 720a-d and the maximum of the interval 710a-d are represented binary. This may correspond in practice to two registers used for the purpose of storing the current interval and thus, the current result of the encoding.

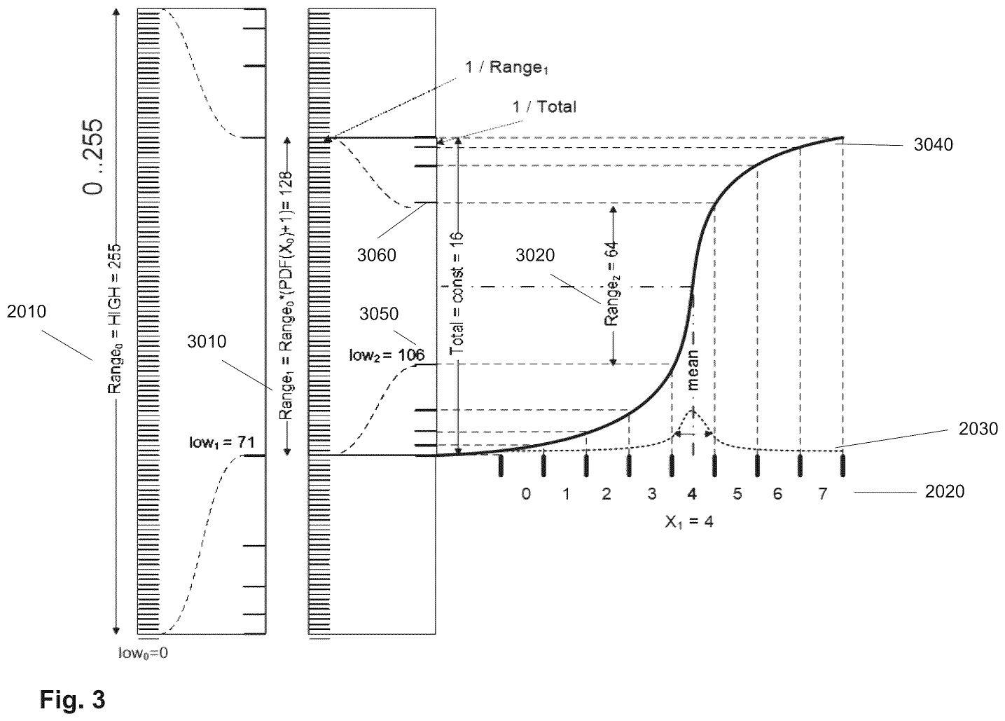

In FIG. 3, the cumulative distribution function CDF 3040 is applied to Range₁=128 starting from Low₁=71 to map the symbols of the alphabet 2020 onto the range. The next symbol of the message is “4”. This results in a new current interval 350-360 that represents the message 44. This interval as shown in FIG. 7b has a new lower bound (current minimum) 720b Low₂=106=0110 1010.b and a new upper bound (current maximum) 710b Low₂+Range₂=170=1010 1010.b. The new Range₂ 3020 equals 64.

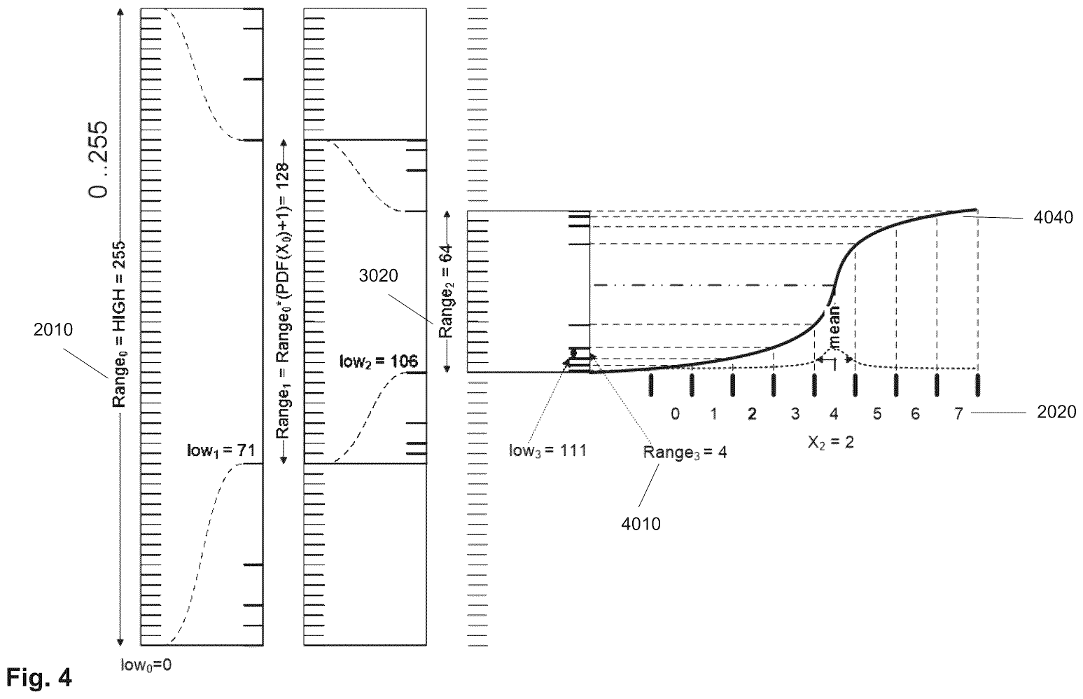

FIG. 4 and FIG. 7c show the next step of the encoding procedure. As Range₂ 3020 is still greater than BOTTOM, this range is divided again according to the cumulative distribution function 4040. This yields for the symbol 2 a low value 720c of Low₃=111=0110 1111.b and a Range₃=4 4010. Thus the message 442 is represented by the range from Low₃ to Low₃+Range₃=115=0111 0011.b 710c.

As the two bits 730 between HIGH and TOP positions are equal, they can be output into the stream 731 as coded bits, see FIG. 7d.

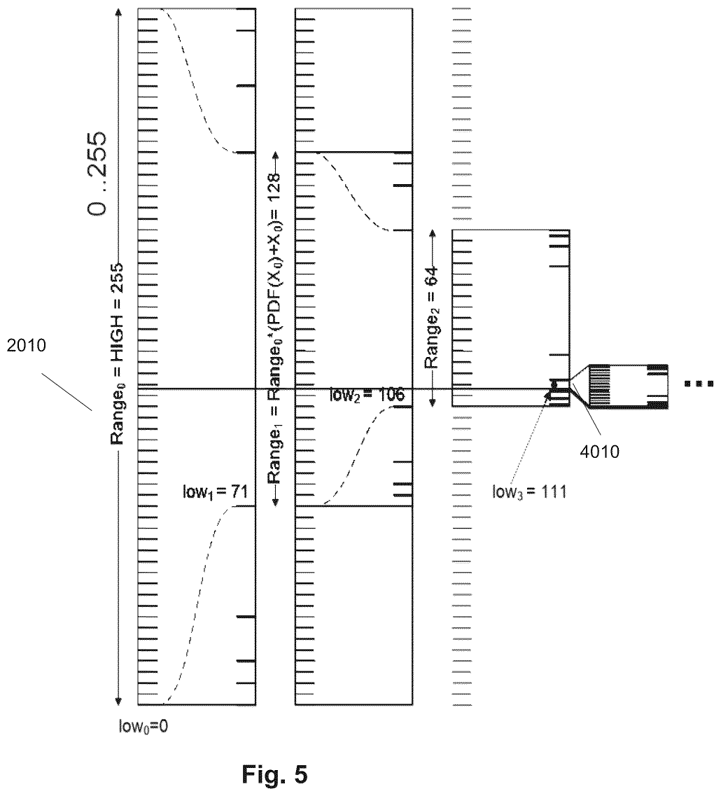

FIG. 5 illustrates that a proper mapping of the symbols onto the range is not possible as Range₃=4 4010 is smaller than BOTTOM=16 and thus a renormalization procedure is necessary. FIG. 7d shows that all bit representations are shifted left until a new Range₄ is greater or equal to BOTTOM. Thus one arrives at the new Range₄=(4<<2)=16 610. The new upper bound 710e is obtained from the present one 710d after left shifting twice. The same shift is applied to Low₃ except for the two coded bits, which are already part of the stream Low₄=188=1011 1100.b 720d.

The message 442 is now encoded by any of the values between 444=01 1011 1100.b and 460=01 1100 1100.b.

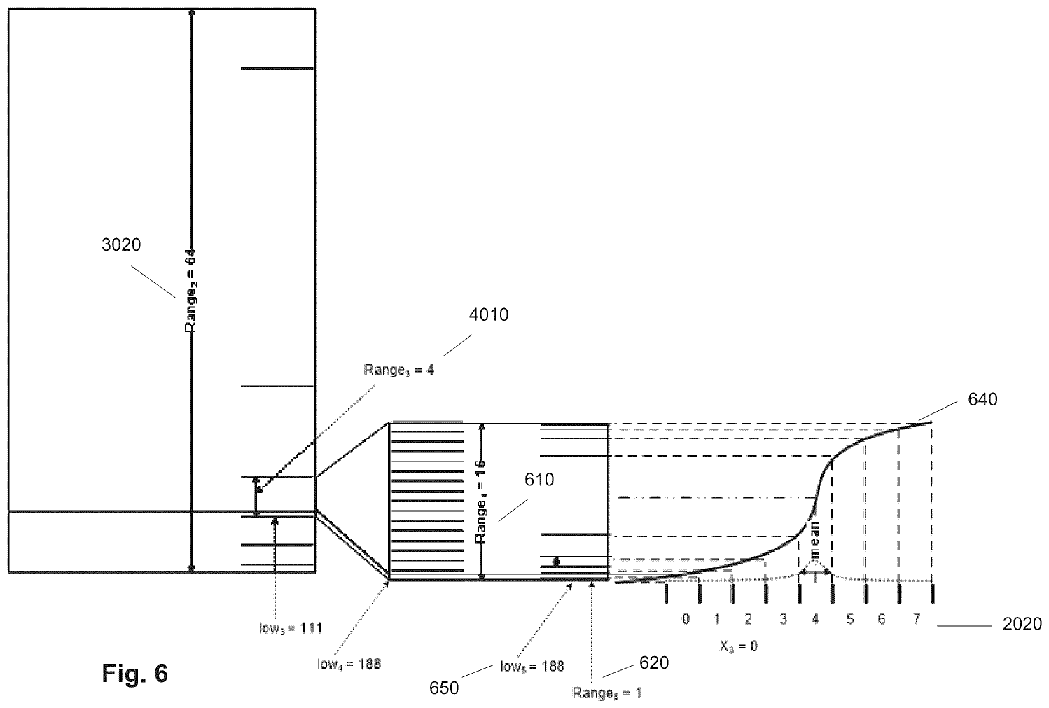

FIG. 6 shows the encoding of the last symbol “0”. The probability distribution yields the lower value of the interval Low₅=188=1011 1100.b 650 and Range₅=1 620. As there is no further symbol to be encoded, Low₅ and Range₅ describe the range interval of the trailing bits, which represent (together with the coded bits) the encoded message. In general, any value from an interval may be used (included into a bitstream) to represent the interval and thus also the coded message (sequence of symbols). Thus, the trailing bits can be chosen arbitrarily from this final range interval. In the present example, Range₅=1 620 yields a single value for the trailing bits, namely Low₅=188=1011 1100.b 650. Thus, the message 4420 is encoded by appending the trailing bits to the coded bits, resulting in the coded value 444=01 1011 1100.b.

### Arithmetic Decoding

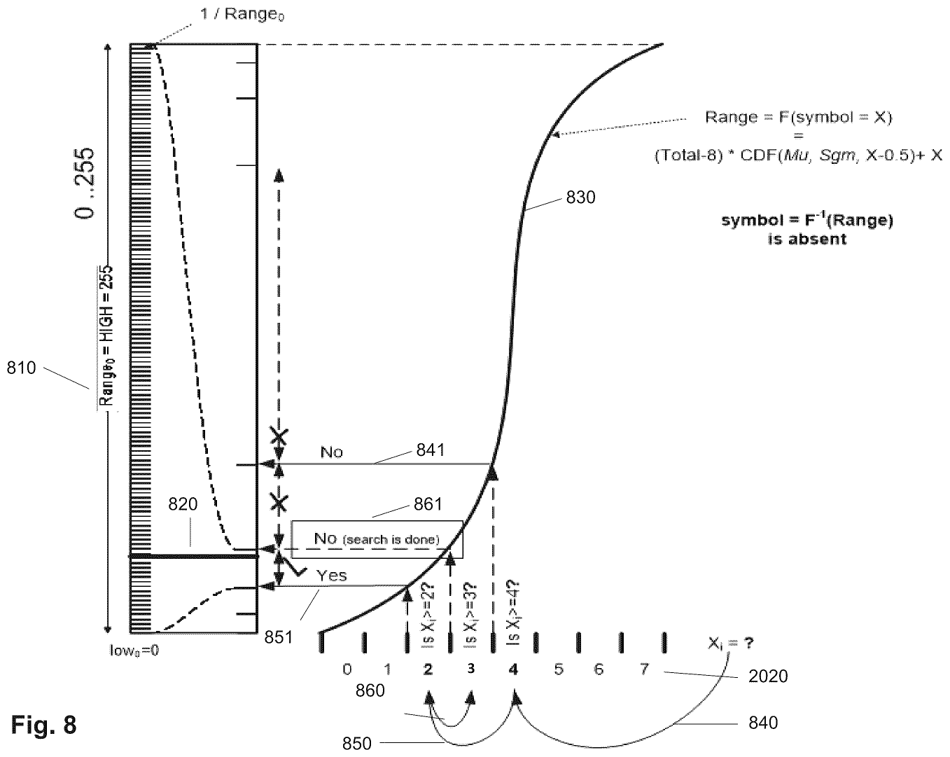

FIG. 8 depicts an exemplary decoding process. The decoder receives the coded values (bits) sequentially. The received coded value 820 is within the full Range₀=HIGH=255 810. The probability distribution function is known at the decoder side and thus the mapping of the symbols 220 onto the range by the cumulative distribution function 830. The decoder does not know an inverse of this mapping, thus the determination of the symbols requires a searching process. The decoder makes a first guess 840 for the encoded symbol by choosing the most likely symbol “4”, calculates a Low value 841 of the range corresponding to this symbol and checks, if the received coded value 820 is higher than this Low value 841.

As the received coded value 820 is smaller than the Low value 841 of the first guess 840, the next guess 850 is a symbol, which is mapped onto lower values within the range, namely one of the symbols “0”, “1”, “2” or “3”. Choosing a Low value approximately in the middle of the remaining interval of the symbols leads to a faster decoding process as less steps are required to obtain the correct symbol. In this example, the next Low value 851 that is chosen for comparison corresponds to the symbol “2”.

The test for symbol “2” yields, that the received coded value is higher than the Low 851 of the range that encodes the symbol “2”. Thus, the received coded value may represent the symbols “2” or “3”. A final check 860 reveals that the Low value 861 of the range corresponding to “3” is higher than the coded value 820. So the received coded value 820 is decoded as symbol “2”.

### Obtaining a Cumulative Distribution Function

As indicated in FIGS. 2 to 4 and 8 and the corresponding explanation, a cumulative distribution function is estimated in order to encode and/or decode symbols. For example, such a distribution function may be a normal (or Gaussian) distribution. However the present disclosure is not limited to normal distributions, any other probability distribution, for example, Laplacian distribution, Cosine distribution, Geometric distribution or the like may be used.

The probability density function (PDF) of a normal distribution with a mean y and a standard deviation a reads

$$φ ( x ) = \frac{1}{\sqrt{2 π {σ}^{2}}} exp ( - \frac{{( x - μ )}^{2}}{2 {σ}^{2}} ) .$$

The corresponding cumulative distribution function (CDF) F(x) takes the form

$$F ( x ) = \frac{1}{2} [ 1 + erf ( \frac{x - μ}{σ \sqrt{2}} ) ] ,$$

wherein

$$erf ( x ) = \frac{2}{\sqrt{π}} {\int }_{0}^{x} exp ( - {τ}^{2} ) d τ$$

is the error function. Said integral cannot be expressed in terms of elementary functions and is therefore known as a special function. There are many different approximations of such special functions which are, for example, based on a Taylor decomposition or a quasi-decomposition supported by exponential and/or logarithmic functions. However, the error function may implemented differently on different software and/or hardware platforms, i.e. the values (or the curve) of the Gaussian distribution on two different platforms may be different, or in other words do not match. This may lead to problems when a signal has been compressed (or encoded) on one platform and is decompressed (or decoded) on another platform. Even small differences, e.g. in ranges which are used for lossless entropy coding, may lead to a wrong output. In particular, due to a difference of the CDF approximation result obtained at the encoder and at the decoder, a mismatch between the encoded and decoded signal may occur.

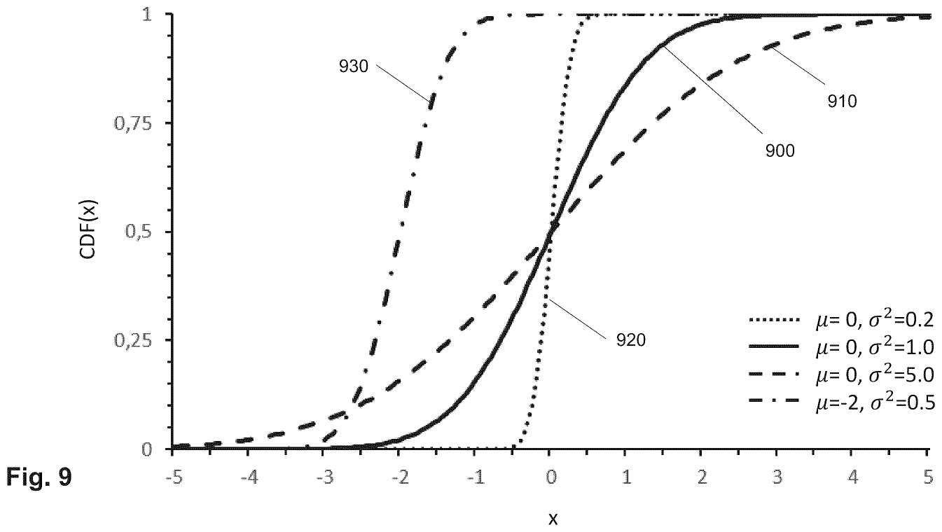

Exemplary CDFs of normal distributions are shown in FIG. 9. The four CDFs differ in variance (σ²); in particular the CDFs have variances 0.2; 0.5; 1; and 5. Three of those exemplary CDFs 900, 910, 920 have a mean μ=0 and the remaining CDF 930 has a mean of μ=−2.

In the present disclosure, a CDF is approximated interval-wise with respective polynomials, while posing constraints on the polynomials within the intervals and/or on the boundary between the intervals. In this manner, a CDF approximation is obtained, which may be used in a variety of applications including arithmetic encoding and decoding of any source data. The constraints may correspond to the characteristics of the CDF to be approximated, such as monotony or continuousness or the like.

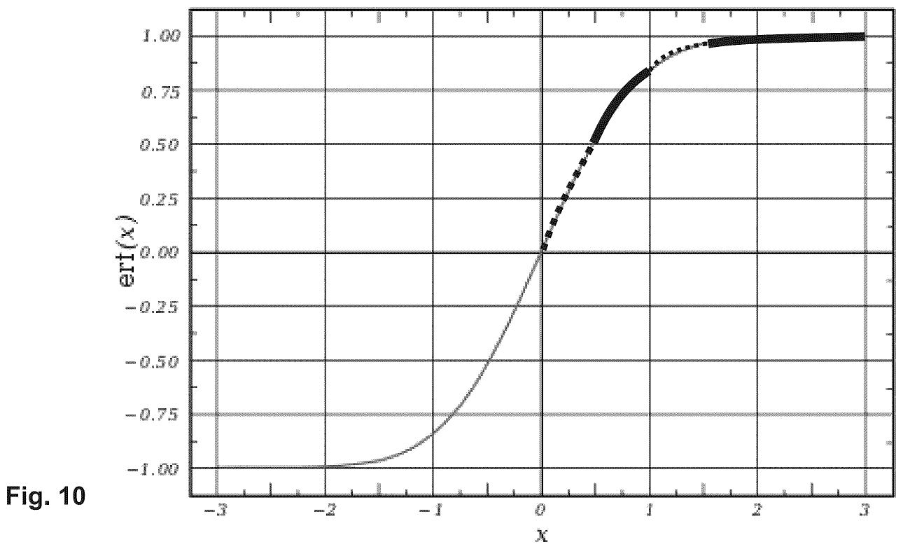

For example, a non-linear function such as a CDF is approximated in a plurality of intervals defining subranges of the domain of definition of the non-linear function. The approximation may be obtained from a function, which may be parametrized and of which the parameters are defined piece-wisely in said plurality of intervals. This is exemplarily shown in FIG. 10, where the error function, which may be used to express the CDF of a Gaussian distribution, is approximated piece-wisely in four intervals with x>0 by first or higher order polynomials. The parameters of the polynomials may then be stored and used later to obtain (define) the approximated CDF for a particular application.

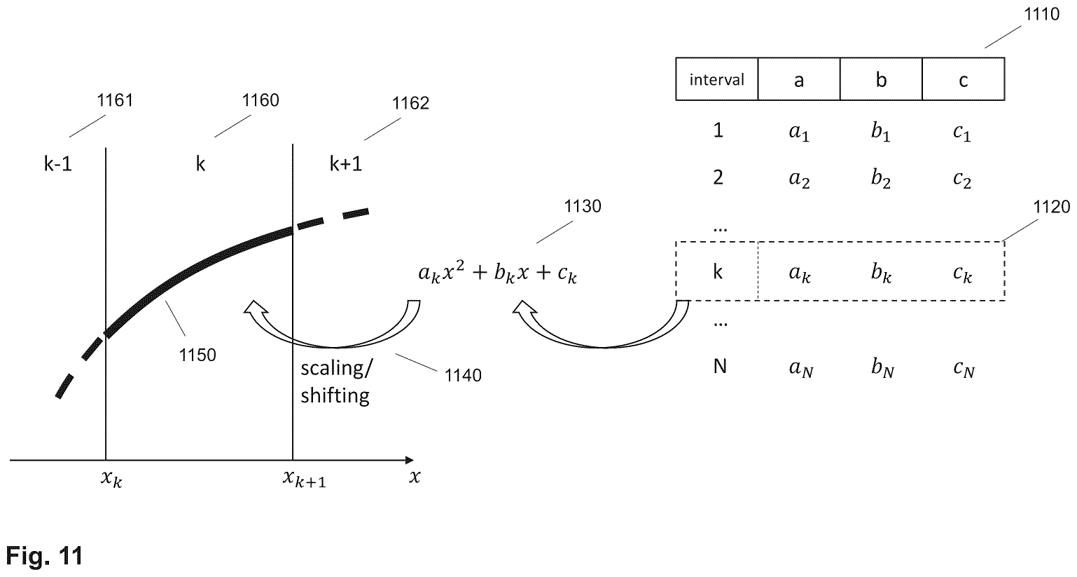

FIG. 11 exemplarily illustrates an obtaining of a CDF from a set of parameters for the application of entropy encoding.

A CDF 1150 is obtained for at least one interval 1160. Said at least one interval 1160, which is included in a plurality of intervals 1160 to 1162, corresponds to a subrange of the value range (x-range in FIG. 9) of the CDF. The intervals within the plurality of intervals may be of a same size or may be of different sizes. It may be advantageous to divide the value range into a predefined number of intervals such as 20, 40, 50, or 100 or any other predefined number. The value range of a CDF may be infinite on one or both sides of the value range for some CDFs. In such a case, the first and/or the last interval may approximate the asymptotic part of the value range. In an exemplary implementation, all intervals apart from the asymptotic interval(s) are of the same length. Moreover, some CDFs are symmetrical, such as the Gaussian CDF. Thus, it may be sufficient to approximate one half of the CDF (e.g. starting by mean and growing) and to obtain the remaining part by mirroring vertically and horizontally. For example, a last interval may have a different size than the remaining intervals including values up to a predefined big number that corresponds to a maximal value of a symbol in the encoding.

The CDF 1150 is obtained based on a function 1130 defined in the at least one interval 1160. The function 1130 is defined in the at least one interval 1160 by parameters 1120 of a second order polynomial. For example, the second order polynomial aₖx²+bₖx+cₖ is defined by the three parameters aₖ, bₖ and cₖ. The second order polynomial fulfills a set of conditions. Any of the parameters aₖ, bₖ and cₖ may be zero. If the parameter aₖ or the parameters aₖ and bₖ are zero, the approximating polynomial has a lower order. Thus, the approximation is not necessarily a second order approximation.

As indicated above, the obtained CDF may represent a CDF of a Gaussian distribution. However, as already indicated, the present disclosure is not limited to Gaussian distributions. There may be further CDFs which have a form that may be difficult to generate by a single function definition, such as CDFs of Laplace, Gibbs, Maxwell-Boltzmann, Beta, Arcsin, Bates, Logits-normal, Irwin-Hall, Kumaraswamy, logit metalog, Marchenko-Pastur, raised cosine, Wigner semicircle, continuous Bernoulli, wrapped Cauchy, wrapped asymmetric Laplace, noncentral chi-squared, Dagum, Cauchy, exponentially modified Gaussian, Gumbel, Holtsmark, hyperbolic, Landau, logistic, skew normal, Student's-T, Tracy-Widom, Voigt and other distributions.

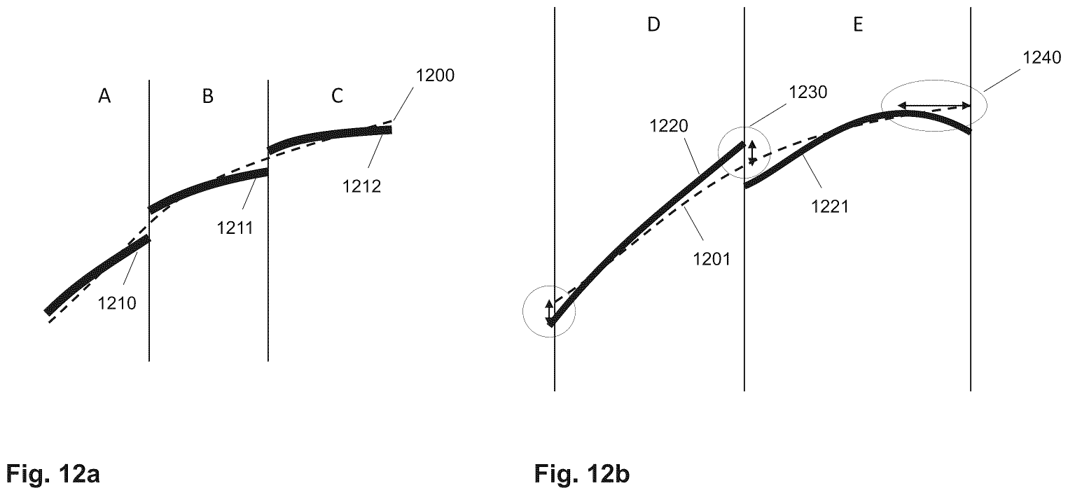

Examples for polynomials fulfilling or violating conditions are illustrated in FIGS. 12a and b. FIG. 12a shows the CDF 1200, which is approximated by polynomials 1210, 1211 and 1212 in three intervals A, B and C. In this example, the polynomials are second-order polynomials with mutually different parameters a, b, and c.

For example, the set of conditions includes that the second order polynomial 1211 and a polynomial 1212 in an adjoining (neighboring) interval provide a monotonically non-decreasing function defining the CDF. Adjoining intervals of the current interval 1160 are the preceding interval 1161 (before) and the consecutive interval 1162 (after).

For example, the set of conditions includes that the second order polynomial 1211 has a non-negative derivative within the interval. This ensures the monotony and non-decreasing character of the approximation. As can be seen in FIG. 12a, there still may be discontinuities at the interval boundaries. However, these discontinuities obey the set of conditions.

The polynomials in FIG. 12a have a non-negative derivative within their respective interval and the function, which is defined by these three exemplary polynomials, is monotonically non-decreasing. In contrast, the two exemplary polynomials 1220 and 1221 in the intervals D and C in FIG. 12b, which are approximating the CDF 1201, are not forming a monotonically non-decreasing function in the region 1230 and the vertex of the second polynomial 1221 lies within the interval. Thus, the polynomial has a negative derivative 1240 within the interval. A non-negative derivative and/or a decreasing function may lead to overlapping ranges for different symbols in the entropy encoding and thus a non-unique mapping of symbols and ranges.

A probability model based on the obtained CDF in the at least one interval is applied in entropy encoding of data into a bitstream. In other words, an estimation for a probability model is provided by the obtained CDF. The entropy encoding may be an arithmetic encoding as explained above in section Arithmetic encoding with reference to FIGS. 2 to 7. In particular, the obtained CDF is applied to define the mapping of the symbols 2020 to the range 2010 of the arithmetic encoder and decoder. The intervals of the approximating function may differ from the intervals used for the mapping of the symbols 2020 to the range 2010 in the arithmetic encoding as illustrated in FIG. 2. The intervals, in which the parameters for the approximation function are defined, may be smaller or larger than the intervals used in the mapping in the encoding, depending on the accuracy of the obtained CDF.

The function 1130, which is defined by the parameters 1120, may specify a predefined CDF with a predefined mean and a predefined standard deviation. In the case of a normal distribution, the predefined CDF may be the standard normal distribution 900 with a predefined mean μ₀=0 and a predefined standard deviation σ₀=1. However, the present disclosure is not limited to these exemplary values.

The function may provide a CDF without applying any further operations. However, in some implementations, the obtaining of the CDF may further include operations of a scaling and/or a shifting 1140 of at least one argument of the function. The CDF may be obtained by shifting at least one argument of the function, which approximates the predefined CDF. An argument of the function is for example, the random variable of the approximated CDF. Such shifting may be performed for one or more intervals out of the plurality of intervals.

For example, the function here is the predefined CDF of a Gaussian distribution with a zero mean and variance 1. The shifting may be performed to obtain a CDF with a target mean μ_{T} of the CDF to be obtained. A shifted argument (x-value) for the function may be obtained by x=s−μ_{T}−0.5, where the symbol s to be encoded is shifted by the target mean μ_{T}. An additional shift of 0.5 is applied to obtain the lower boundary of the intervals in the mapping of the symbols 2020 to the CDF 2040 as it is explained above with reference to FIG. 2.

A scaling may be applied to at least one argument of the function to obtain the CDF within at least one interval. Such scaling may be performed in addition or alternatively to a shifting in one or more intervals out of the plurality of intervals.

For example, a scaling is applied to align a target standard deviation σ_{T} and the predefined standard deviation σ₀. The scaling may be obtained for example by using the scaled variable

$$v = \frac{- x}{{σ}_{T} + ϵ}$$

as argument, wherein a small number ϵ>0 is added to avoid a division by zero.

The function may be defined in one or more intervals out of the plurality of intervals by a linear polynomial. There may be regions in which a linear approximation does not reduce the accuracy of the CDF significantly. For example, this may be the case in intervals close to the mean or in intervals in which the CDF is approximately zero or one. In these exemplary intervals the slope of the function shows only little influence by a value x within the value range. For example, the function in the last interval out of the plurality of intervals is defined by a linear polynomial. In said last interval the CDF to be approximated may approach its limiting value one. Thus, the number of parameters, which specify the polynomial of the last interval, may be reduced.

When the function is approximating a predefined CDF as explained above, the function may be point-symmetric with respect to the predefined mean. In other words, the function f(x) may be point-symmetric to the point (μ, f(μ)). This is the case for Gaussian CDFs, exemplarily depicted in FIG. 9. The function may be defined in intervals including values higher than said predefined mean. For example, the function specifying a standard normal CDF with a mean μ=0 and a standard deviation σ=1, is defined for x>0. To obtain the CDF for x<0 based on this function, the point-symmetry may be exploited. This may reduce the number of intervals in which the function approximates the predefined CDF, and thus the number of parameters to be used and stored may be reduced.

A look-up table (LUT) may provide the parameters for each interval out of the plurality of intervals. However, the present disclosure is not limited to a LUT providing the parameters. The parameters may be stored in any format. FIG. 11 exemplarily provides such a LUT 1110, which includes a subset of parameters 1120 for each interval k. In the exemplary case, when the last interval is specified by a linear polynomial, the parameter a_{N}=0 may not be included in the set of parameters. This reduces the number of parameters to be stored.

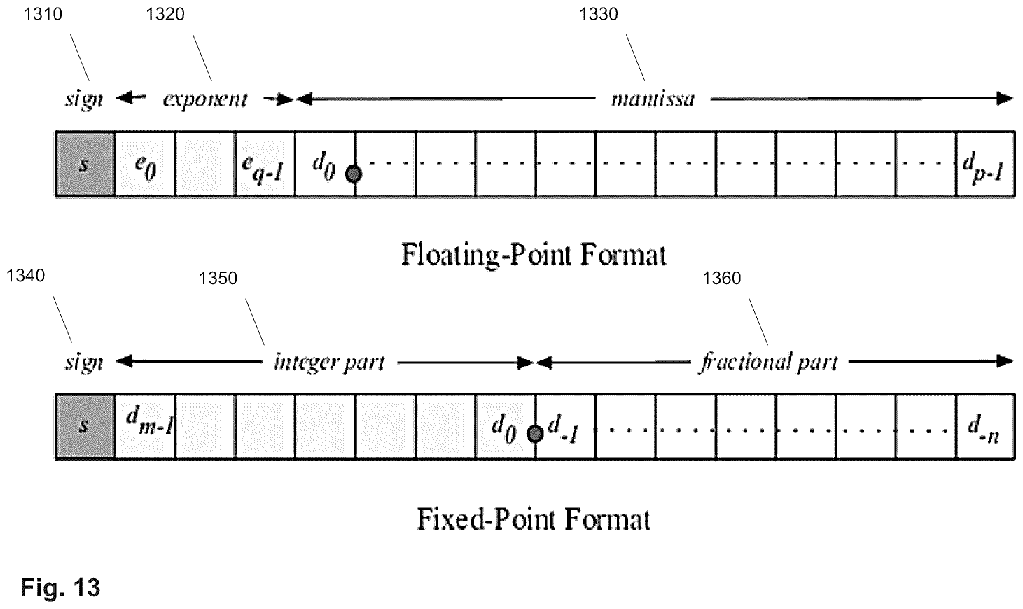

The parameters may be provided in a fixed-point representation having a predetermined precision. An illustration of the fixed-point format is given in FIG. 13. A number x may be written in a fixed-point representation as

$$x = s \cdot ( {d}_{m - 1} … {d}_{0} . {d}_{- 1} … {d}_{- n} ) = s \cdot {\sum }_{i = - n}^{m - 1} {d}_{i} {b}^{i} ,$$

where x is a number made of m+n digits. The m first digits represent the integer part 1350 while the n last digits represent the fractional part 1360, s is the sign 1340 of x. For example, the basis may be chosen as b=2.

A parameter in a fixed-point format may be represented by an integer and a predetermined precision. For example, 3.14=314/100 may be represented by the integer 314 and the precision factor 1/100.

In an exemplary implementation, a 32 bit integer may be used for each parameter. In the case, when the function is defined in 40 intervals by second order polynomials (i.e. 3 parameters per polynomial), 40×3×32 bits are required to define said function.

Such a fixed-point representation together with a predetermined precision provides a same precision and a same fixed-point representation leading to the same values on different types of platforms. To ensure same results obtained by processing the parameters on different platforms, the precision of intermediate results may be adapted to the predetermined precision. This may include a predetermined set of rules for reducing precision of intermediate results. For example, the rules may include rules for rounding and/or clipping of numbers in the fixed-point format. Such rules are to be obeyed at any processor architecture on which the CDF is obtained for the entropy encoding, which then leads to compatibility and ensures a synchronized entropy encoding and decoding.

Such a segmentwise (intervalwise) approximation by second order polynomials as a basis for a CDF used in entropy coding eliminates the need for a (plat-form dependent) implementation of special functions such as the error function. Using simple operations like scaling and shifting allows for obtaining the same values of the CDF on different hardware and/or software platforms.

However, the present disclosure is not limited to parameters in fixed-point format. For example, a floating point format, which is illustrated in FIG. 13 may be used. A floating-point number x in base b is defined by

$$x = s \cdot ( {d}_{0} . {d}_{1} … {d}_{p - 1} ) \cdot {b}^{e} = s \cdot m \cdot {b}^{e - p + 1} ,$$

where s is the sign 1310, m is the mantissa 1330 with digits 0≤dᵢ<b, 0≤i≤p−1, p is the precision and e is the exponent 1320.

In an exemplary implementation the CDF is obtained for a value x=s−μ−0.5 within the at least one interval, where s represents the symbol to be encoded and y is the mean of the CDF to be obtained. The CDF is obtained for x smaller than zero by

$$C D F ( x ) = M - ( {a}_{i} {v}^{2} + {b}_{i} v + {c}_{i} ) + s ,$$

wherein aᵢ, bᵢ and cᵢ are the parameters of a second order polynomial within the at least one interval. The parameter

$$v = \frac{- x}{{σ}_{left} + ϵ}$$

scales the value x by the standard deviation σ_{left} of the CDF for x smaller than zero. A small predetermined parameter ϵ>0 avoids a division by zero. For example, the predetermined parameter epsilon may depend on the precision used for the parameters.

The multiplication factor M, which is related to the predetermined precision 1/M, is defined by M=total−sₘₐₓ−1, where total is related to the number of bits used in entropy encoding and sₘₐₓ is the maximal value of a symbol to be encoded. In the exemplary entropy encoding as explained in section Arithmetic encoding with reference to FIG. 2, a total of 16 is used to encode the eight symbols of the alphabet 220 {0, 1, 2, 3, 4, 5, 6, 7}, thus with sₘₐₓ=7 the multiplication factor M=8.

The CDF is obtained for x greater than zero by

$$C D F ( x ) = {a}_{i} {v}^{2} + {b}_{i} v + {c}_{i} + s ,$$

wherein aᵢ, bᵢ and cᵢ are the parameters of a second order polynomial within the at least one interval. The parameter

$$v = \frac{x}{{σ}_{r i g h t} + ϵ}$$

scales the value x by the standard deviation σ_{left} of the CDF for x greater than zero. A small predetermined parameter ϵ>0 avoids a division by zero.

In the corresponding decoding, a CDF is obtained analogously to the encoding in order to properly reconstruct the encoded data from the bitstream. Thus, for at least one interval 1160 out of a plurality of intervals 1160 to 1162, a CDF 1150 is obtained. The plurality of intervals is defined analogously to the encoding. Thus, the plurality of intervals may be predetermined, for example, being defined by a standard or signaled to the decoder. In the at least one interval 1160 a function 1130 is defined by parameters 1120 of a second order polynomial. The CDF 1150 is obtained based on said function 1130. The obtaining may include a scaling and/or shifting 1140 of arguments of said function.

The function 1130 may be approximating a predefined CDF. The predefined CDF may have a predefined mean and a predefined standard deviation. For example, the predefined CDF is a standard CDF 900 of a Gaussian distribution with predefined mean μ₀=0 and predefined standard deviation σ₀=1. The obtained CDF may represent a CDF of a Gaussian distribution. However, as already indicated the present disclosure is not limited to Gaussian distributions.

Data is entropy decoded from a bitstream by applying a probability model based on the obtained CDF 1150 in the at least one interval 1160. The entropy decoding may be an arithmetic decoding as explained above in section Arithmetic decoding with reference to FIG. 8. The ranges of the arithmetic decoder are defined according to the CDF.

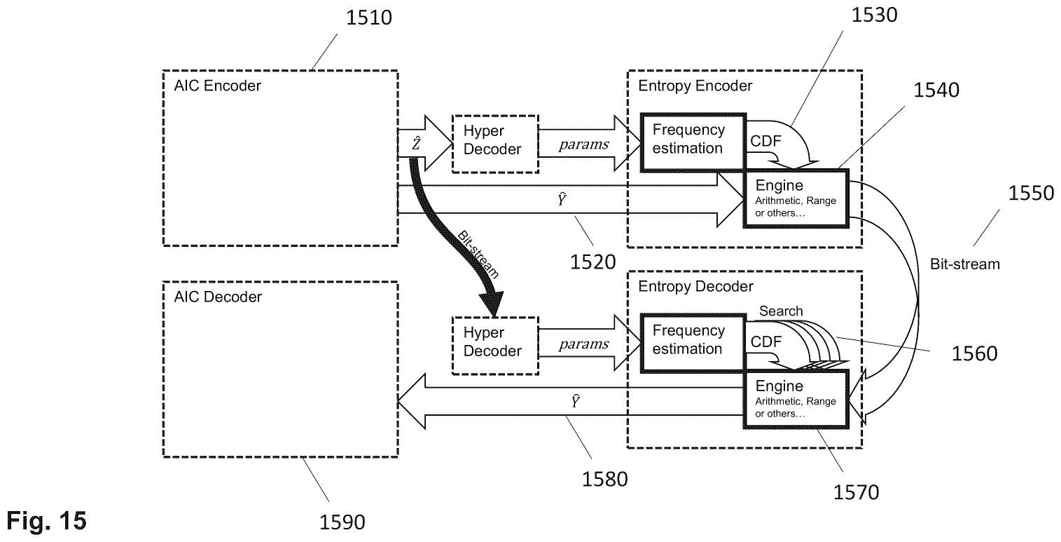

An exemplary scheme of entropy encoding and decoding is shown in FIG. 15. Data to be encoded 1520 into a bitstream 1550 may be obtained for example from the encoder part 1510 of an autoencoding neural network, which is explained in detail in section Autoencoders and unsupervised learning. The CDF 1530 used in the entropy encoding 1540 may be obtained as explained above. In the decoding, a CDF 1560 is obtained as explained above. For correct decoding 1570, the CDF 1560 applied in the decoder should be the same as the CDF 1530 applied in the encoder, which is achieved by the method explained above. The data 1580 is decoded. This may be for example a latent space representation that may be further processed by the decoding part 1590 of an autoencoding neural network.

The encoding and decoding as explained above may be applied, for example, within variational autoencoders, hybrid coders or hybrid AI coders. Some exemplary implementations of such types of encoders and decoders, which may use the obtained CDF, are explained in the following sections.

The second order polynomial fulfills a set of conditions. For example, the set of conditions includes that the second order polynomial 1211 and a polynomial 1212 in an adjoining (neighboring) interval provide a monotonically non-decreasing function defining the CDF.

For example, the set of conditions includes that the second order polynomial 1211 has a non-negative derivative within the interval. This ensures the monotony and non-decreasing character of the approximation of the CDF, as can be seen in the example in FIG. 12a. The discontinuities obey the set of conditions.

The function defined by the parameters may provide a CDF without applying any further operations. In some implementations, the obtaining of the CDF may further include scaling and/or shifting 1140 of at least one argument of the function. The CDF may be obtained by shifting at least one argument of the function, which approximates the predefined CDF. Such shifting may be performed for one or more intervals out of the plurality of intervals.

For example, the x-value of the function, which is defined as aₖx²+bₖx+cₖ in interval k, may be shifted based on a target mean μ_{T} of the CDF that is to be obtained. A shifted x-value for the function may be obtained by x=s−μ_{T}−0.5, where the symbol s to be encoded is shifted by the target mean μ_{T}. An additional shift of 0.5 is applied to obtain the lower boundary of the intervals in the mapping of the symbols 2020 to the CDF 2040 as it is explained above with reference to FIG. 2.

A scaling may be applied to at least one argument of the function to obtain the CDF. Such scaling may be performed in addition or alternatively to a shifting in one or more intervals out of the plurality of intervals.

For example, a scaling is applied to align a target standard deviation σ_{T} and the predefined standard deviation σ₀ of the approximated CDF. A scaled variable

$$v = \frac{- x}{{σ}_{T} + ϵ}$$

may be used as argument. The scaled variable v includes the target standard deviation σ_{T} and a small number ϵ>0 that is added to avoid a division by zero. The scaled variable v is based on a function approximating a predefined CDF with a standard deviation σ₀=1.

FIG. 9 illustrates CDFs that may be obtained by a scaling and/or shifting from the standard normal CDF 900. To obtain CDFs 910 and 920 from the standard normal CDF 900, a scaling of the argument x is performed to match the respective target standard deviations. To obtain CDF 930 a scaling and a shifting of the argument x are performed.

The function may be defined in one or more intervals out of the plurality of intervals by a linear polynomial. For example, in intervals close to the mean or in intervals in which the CDF is approximately zero or one, a linear approximation may not reduce the accuracy of the CDF significantly. In these exemplary intervals the slope of the function shows only little influence by a value x within the value range. In other words, the parameter a in the polynomial ax²+bx+c is small compared to parameters b and/or c. For example, the function in the last interval out of the plurality of intervals may be defined by a linear polynomial. In said last interval the CDF to be approximated may approach its limiting value one. Thus, the number of parameters may be reduced. The number of parameters for each interval could be limited to 3 for a general case and to 2 for some cases (for example only “a and b” or only “a and c”).

Analogously to the encoding, the number of intervals may be reduced for point-symmetric functions. A predefined CDF may be point-symmetric with respect to its predefined mean value, i.e. the point (μ, CDF(μ)). Correspondingly, a function f(x) approximating said predefined CDF is point-symmetric to the point (μ, f(μ)). Thus, the function may be defined in intervals including values higher than said predefined mean. For example, the function specifying a normal CDF with a mean μ=0, is defined for x>0. The function f(x) for values x smaller than the predefined mean value μ₀ may be obtained by f(μ₀+x)=−f(μ₀−x).

Analogously, to the encoding, the parameters may be provided in a LUT 1110 for each interval. The LUT can contain 3 columns (one column for each of the 3 parameters a, b and c) or 2 columns with parameters of the parabolic polynomial (some parameters of 2^{nd} degree polynomial could be skipped or omitted for some cases, e.g. one column for each of two parameters, e.g. only “a and b” or only “a and c” as described above). The parameters may be provided in a fixed-point format having a predetermined precision. The fixed-point format is explained above with reference to FIG. 13.

Such a fixed-point representation together with a predetermined precision provides a same precision and a same fixed-point representation leading to the same values on different types of platforms, e.g. during encoding and decoding on different platforms. The precision of intermediate results may be adapted to the predetermined precision. This may include a predetermined set of rules for reducing precision of intermediate results, which is the same for all platforms. For example, the rules may include rules for rounding and/or clipping of numbers in the fixed-point format. Such rules are to be obeyed at any processor architecture on which the CDF is obtained for the entropy decoding, which then leads to compatibility and ensures a synchronized entropy encoding and decoding.

In an exemplary implementation the CDF used in the entropy decoding is obtained analogously to the encoding for a value x=s−μ−0.5 within the at least one interval, where s represents the symbol to be encoded and y is the mean of the CDF to be obtained. The CDF is obtained for x smaller than zero by

$$CDF ( x ) = M - ( {a}_{i} {v}^{2} + {b}_{i} v + {c}_{i} ) + s ,$$

wherein aᵢ, bᵢ and cᵢ are the parameters of a second order polynomial within the at least one interval. The parameter

$$v = \frac{- x}{{σ}_{left} + ϵ}$$

scales the value x by the standard deviation σ_{left} of the CDF for x smaller than zero. A small predetermined parameter ϵ>0 avoids a division by zero. For example, the predetermined parameter epsilon may depend on the precision used for the parameters.

The multiplication factor M, which is related to the predetermined precision 1/M, is defined by M=total−sₘₐₓ−1, where total is related to the number of bits used in entropy encoding and sₘₐₓ is the maximal value of a symbol to be encoded.

The CDF is obtained for x greater than zero by

$$CDF ( x ) = {a}_{i} {v}^{2} + {b}_{i} v + {c}_{i} + s ,$$

wherein aᵢ, bᵢ and cᵢ are the parameters of a second order polynomial within the at least one interval. The parameter

$$v = \frac{x}{{σ}_{right} + ϵ}$$

scales the value x by the standard deviation σ_{left} of the CDF for x greater than zero.

As explained above, a CDF used in entropy encoding is specified by a set of parameters within a plurality of intervals. The plurality of intervals corresponds to a subrange of the value range of the CDF. For an interval within said plurality of intervals, a subset of parameters is obtained. The subset of parameters defines a second order polynomial within said interval. The polynomial approximates the CDF. This is exemplarily shown in FIG. 11, where the second order polynomial 1130 is defined by the subset of parameters 1120.

The CDF specified by a set of parameters may be applied in entropy coding of still pictures, video pictures, audio signals (e.g. multi-channel audio signals), respectively entropy coding and decoding of data related to still pictures, video pictures and audio signals but is not limited to those.

In the approximation a set of conditions is fulfilled. As explained above, examples for conditions are illustrated in FIGS. 12a and b. For example, the set of conditions includes that the second order polynomial 1211 and a polynomial 1212 in an adjoining interval provide a monotonically non-decreasing function defining the CDF. For example, the set of conditions includes that the second order polynomial 1211 has a non-negative derivative within the interval.

The exemplary polynomials in FIG. 12a have a non-negative derivative within their respective interval and the function, which is defined by these three exemplary polynomials, is monotonically non-decreasing.

The function 1130, which is defined by the parameters 1120, may specify a predefined CDF with a predefined mean and a predefined standard deviation. In the case of a normal distribution, the predefined CDF may be the standard normal distribution 900 with a predefined mean μ₀=0 and a predefined standard deviation σ₀=1. However, the present disclosure is not limited to these exemplary values.

The CDF to be approximated may be a Gaussian CDF. However the present disclosure is not limited to a Gaussian CDF, any other CDF including the examples listed above may be approximated.

The function may be defined in one or more intervals out of the plurality of intervals by a linear polynomial. There may be regions in which a linear approximation does not reduce the accuracy of the CDF significantly. For example, this may be the case in intervals close to the mean or in intervals in which the CDF is approximately zero or one. In these exemplary intervals the slope of the function shows only little influence by a value x within the value range. In an exemplary implementation, the function in the last interval out of the plurality of intervals is defined by a linear polynomial. In said last interval the CDF to be approximated may approach its limiting value one, i.e. the last interval includes all remaining values of the value range higher than the right boundary of the preceding interval. Thus, the number of parameters, which specify the polynomial of the last interval, may be reduced.

When the function is approximating a predefined CDF as explained above, the function may be point-symmetric with respect to the predefined mean. In other words, the function f(x) may be point-symmetric to the point (μ, f(μ)). This is the case for Gaussian CDFs, exemplarily depicted in FIG. 9. The function may be defined in intervals including values higher than said predefined mean. To obtain a CDF with a mean μ=0 for x<0 based on this function, the point-symmetry may be exploited. This may reduce the number of intervals in which the function approximates the predefined CDF, and thus the number of parameters to be used and stored may be reduced.

The parameters 1120 for each interval are stored in a look-up table (LUT) 1110. However, the present disclosure is not limited to a LUT providing the parameters. The parameters may be stored in any format. FIG. 11 exemplarily provides such a LUT 1110, which includes a subset of parameters 1120 for each interval k.

The parameters may be provided in a fixed-point format having a predetermined precision. The fixed-point format is explained above with reference to FIG. 13.

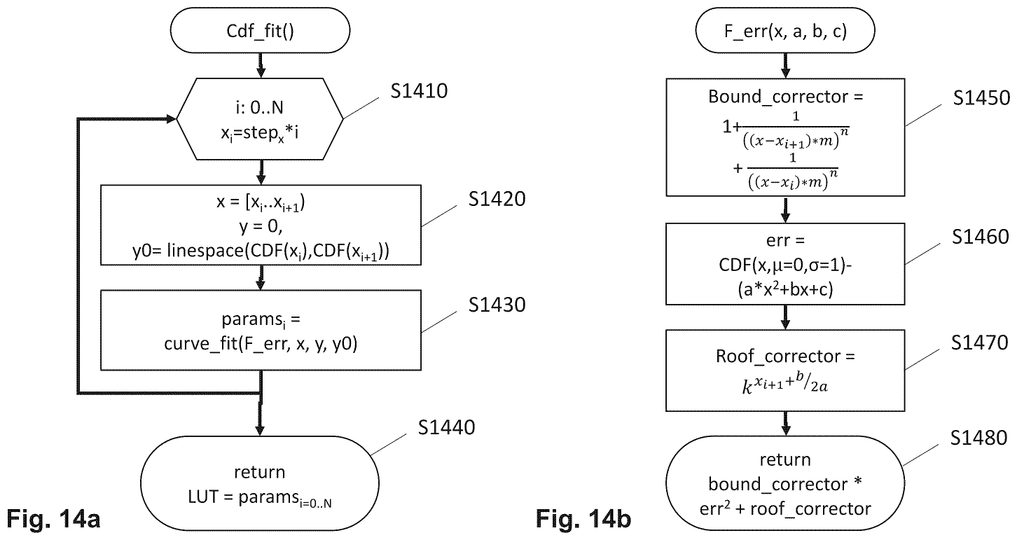

An exemplary obtaining of a set of parameters is shown in FIG. 14a. The x-value range of the CDF to be approximated is divided S1410 in N intervals of step size stepₓ. For each xᵢ in this exemplary implementation, a value of the CDF to be approximated yᵢ=CDF(xᵢ) is obtained S1420. In the following step S1430 parameters for an interval i are obtained. The parameters may be obtained by a curve fit, such as a least-squares fit or any other fitting method.

The obtaining of the parameters may include the optimization of a cost function. The optimization may be performed once at an initial design of the LUT. In the case the LUT is provided by a standard the optimization may be performed once for said standard. Such a cost function includes a difference between the second order polynomial and the CDF. An exemplary cost function is obtained in FIG. 14b. This exemplary cost function F_err(x, a, b, c) depends on the squared difference of the CDF to be approximated and the second order polynomial ax²+bx+c S1460.

Such a cost function may further include a penalty, which enhances the difference between the second order polynomial and the CDF at the boundaries of said interval. An exemplary implementation for such a penalty may be the bound corrector multiplier S1450 in FIG. 14b. This bound corrector is multiplied with the squared error in S1480 to enhance the squared error at the interval boundaries xᵢ and xᵢ₊₁.

Thus, a bound corrector multiplier in an exemplary implementation may have the form

$$bound\_corrector = 1 + \frac{1}{{( ( x - {x}_{i + 1} ) * m )}^{n}} + \frac{1}{{( ( x - {x}_{i} ) * m )}^{n}} ,$$

where m depends on number of parameters in said set of parameters and n is adapted to obtain a suitable correction of the error. In the example of FIG. 14b the values are chosen as m=10³ and n=10. The bound corrector enhances, for example, the squared distance 1230 in FIG. 12b.

The cost function may further include a penalty, which is added when a vertex of a parabola defined by the second order polynomial is within said interval or left of said interval.

An exemplary implementation for such a penalty may be the roof corrector S1470 in FIG. 14b. Such a roof corrector adds a high penalty for negative derivatives which appear when the vertex of parabola is inside or left of the particular interval. The roof corrector may have the form

$$roof\_corrector = {k}^{{x}_{i + 1} + b / 2 a} ,$$

where the base k is chosen such that the penalty is enhanced in the case when the vertex of parabola is inside or left of the particular interval and reduced when the vertex is right of the particular interval. The penalty is based on the distance between the vertex of the parabola and the right interval boundary xᵢ₊₁+b/2a. In an exemplary implementation in FIG. 14b, k may take the value 10¹⁰⁰. In FIG. 12b, the roof corrector adds a large penalty in interval E as the vertex is inside interval E and thus there is a negative derivative in region 1240.

An exemplary cost function including the bound corrector multiplier and the roof corrector may take the form F_err=bound_corrector*err²+roof_corrector, which is obtained in S 1480 in FIG. 14b. After repeating steps S1410 to S1430 for each interval out of the N intervals, a set of parameters is obtained in S1440.

In the obtaining of the parameters an initial state of parameters (a, b, c) may be used with values corresponding to a linear approximation.

### Artificial Neural Networks

Artificial neural networks (ANN) or connectionist systems are computing systems vaguely inspired by the biological neural networks that constitute animal brains. Such systems “learn” to perform tasks by considering examples, generally without being programmed with task-specific rules. For example, in image recognition, they might learn to identify images that contain cats by analyzing example images that have been manually labeled as “cat” or “no cat” and using the results to identify cats in other images. They do this without any prior knowledge of cats, for example, that they have fur, tails, whiskers and cat-like faces. Instead, they automatically generate identifying characteristics from the examples that they process.

An ANN is based on a collection of connected units or nodes called artificial neurons, which loosely model the neurons in a biological brain. Each connection, like the synapses in a biological brain, can transmit a signal to other neurons. An artificial neuron that receives a signal then processes it and can signal neurons connected to it.

In ANN implementations, the “signal” at a connection is a real number, and the output of each neuron is computed by some non-linear function of the sum of its inputs. The connections are called edges. Neurons and edges typically have a weight that adjusts as learning proceeds. The weight increases or decreases the strength of the signal at a connection. Neurons may have a threshold such that a signal is sent only if the aggregate signal crosses that threshold. Typically, neurons are aggregated into layers. Different layers may perform different transformations on their inputs. Signals travel from the first layer (the input layer), to the last layer (the output layer), possibly after traversing the layers multiple times.

The original goal of the ANN approach was to solve problems in the same way that a human brain would. Over time, attention moved to performing specific tasks, leading to deviations from biology. ANNs have been used on a variety of tasks, including computer vision, speech recognition, machine translation, social network filtering, playing board and video games, medical diagnosis, and even in activities that have traditionally been considered as reserved to humans, like painting.

The name “convolutional neural network” (CNN) indicates that the network employs a mathematical operation called convolution. Convolution is a specialized kind of linear operation. Convolutional networks are neural networks that use convolution in place of a general matrix multiplication in at least one of their layers.

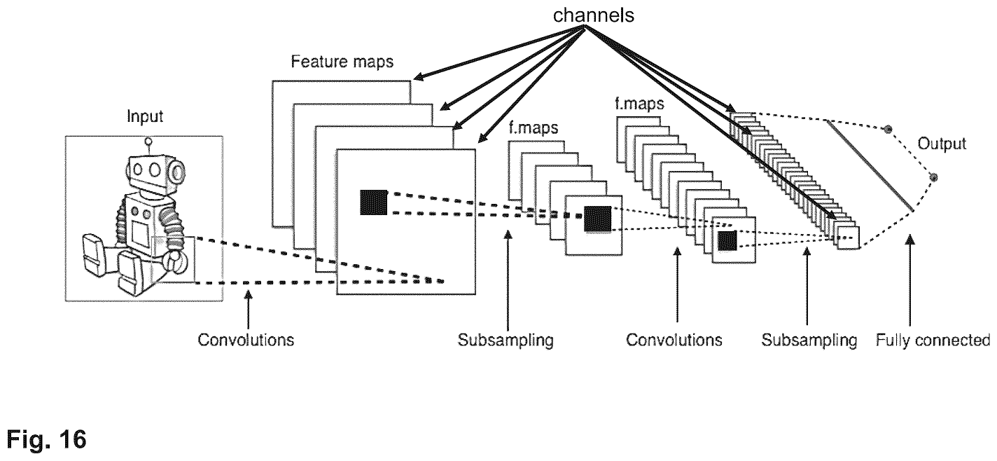

FIG. 16 schematically illustrates a general concept of processing by a neural network such as the CNN. A convolutional neural network consists of an input and an output layer, as well as multiple hidden layers. Input layer is the layer to which the input (such as a portion of an image as shown in FIG. 16) is provided for processing. The hidden layers of a CNN typically consist of a series of convolutional layers that convolve with a multiplication or other dot product. The result of a layer is one or more feature maps (f.maps in FIG. 16), sometimes also referred to as channels. There may be a subsampling involved in some or all of the layers. As a consequence, the feature maps may become smaller, as illustrated in FIG. 16. The activation function in a CNN is usually a ReLU (Rectified Linear Unit) layer, and is subsequently followed by additional convolutions such as pooling layers, fully connected layers and normalization layers, referred to as hidden layers because their inputs and outputs are masked by the activation function and final convolution. Though the layers are colloquially referred to as convolutions, this is only by convention. Mathematically, it is technically a sliding dot product or cross-correlation. This has significance for the indices in the matrix, in that it affects how the weight is determined at a specific index point.

When programming a CNN for processing images, as shown in FIG. 16, the input is a tensor with shape (number of images)×(image width)×(image height)×(image depth). Should be known that image depth can be constitute of channels of image. After passing through a convolutional layer, the image becomes abstracted to a feature map, with shape (number of images)×(feature map width)×(feature map height)×(feature map channels). A convolutional layer within a neural network should have the following attributes. Convolutional kernels defined by a width and height (hyper-parameters). The number of input channels and output channels (hyper-parameter). The depth of the convolution filter (the input channels) should be equal to the number channels (depth) of the input feature map.

In the past, traditional multilayer perceptron (MLP) models have been used for image recognition. However, due to the full connectivity between nodes, they suffered from high dimensionality, and did not scale well with higher resolution images. A 1000×1000-pixel image with RGB color channels has 3 million weights, which is too high to feasibly process efficiently at scale with full connectivity. Also, such network architecture does not take into account the spatial structure of data, treating input pixels which are far apart in the same way as pixels that are close together. This ignores locality of reference in image data, both computationally and semantically. Thus, full connectivity of neurons is wasteful for purposes such as image recognition that are dominated by spatially local input patterns.

Convolutional neural networks are biologically inspired variants of multilayer perceptrons that are designed to emulate the behavior of a visual cortex. These models mitigate the challenges posed by the MLP architecture by exploiting the strong spatially local correlation present in natural images. The convolutional layer is the core building block of a CNN. The layer's parameters consist of a set of learnable filters (the above-mentioned kernels), which have a small receptive field, but extend through the full depth of the input volume. During the forward pass, each filter is convolved across the width and height of the input volume, computing the dot product between the entries of the filter and the input and producing a 2-dimensional activation map of that filter. As a result, the network learns filters that activate when it detects some type of feature at some spatial position in the input.

Stacking the activation maps for all filters along the depth dimension forms the full output volume of the convolution layer. Every entry in the output volume can thus also be interpreted as an output of a neuron that looks at a small region in the input and shares parameters with neurons in the same activation map. A feature map, or activation map, is the output activations for a given filter. Feature map and activation has same meaning. In some papers it is called an activation map because it is a mapping that corresponds to the activation of different parts of the image, and also a feature map because it is also a mapping of where a certain kind of feature is found in the image. A high activation means that a certain feature was found.

Another important concept of CNNs is pooling, which is a form of non-linear down-sampling. There are several non-linear functions to implement pooling among which max pooling is the most common. It partitions the input image into a set of non-overlapping rectangles and, for each such sub-region, outputs the maximum.

Intuitively, the exact location of a feature is less important than its rough location relative to other features. This is the idea behind the use of pooling in convolutional neural networks. The pooling layer serves to progressively reduce the spatial size of the representation, to reduce the number of parameters, memory footprint and amount of computation in the network, and hence to also control overfitting. It is common to periodically insert a pooling layer between successive convolutional layers in a CNN architecture. The pooling operation provides another form of translation invariance.

The pooling layer operates independently on every depth slice of the input and resizes it spatially. The most common form is a pooling layer with filters of size 2×2 applied with a stride of 2 at every depth slice in the input by 2 along both width and height, discarding 75% of the activations. In this case, every max operation is over 4 numbers. The depth dimension remains unchanged. In addition to max pooling, pooling units can use other functions, such as average pooling or l2-norm pooling. Average pooling was often used historically but has recently fallen out of favour compared to max pooling, which often performs better in practice. Due to the aggressive reduction in the size of the representation, there is a recent trend towards using smaller filters or discarding pooling layers altogether. “Region of Interest” pooling (also known as ROI pooling) is a variant of max pooling, in which output size is fixed and input rectangle is a parameter. Pooling is an important component of convolutional neural networks for object detection based on Fast R-CNN architecture.

The above-mentioned ReLU is the abbreviation of rectified linear unit, which applies the non-saturating activation function. It effectively removes negative values from an activation map by setting them to zero. It increases the nonlinear properties of the decision function and of the overall network without affecting the receptive fields of the convolution layer. Other functions are also used to increase nonlinearity, for example the saturating hyperbolic tangent and the sigmoid function. ReLU is often preferred to other functions because it trains the neural network several times faster without a significant penalty to generalization accuracy.

After several convolutional and max pooling layers, the high-level reasoning in the neural network is done via fully connected layers. Neurons in a fully connected layer have connections to all activations in the previous layer, as seen in regular (non-convolutional) artificial neural networks. Their activations can thus be computed as an affine transformation, with matrix multiplication followed by a bias offset (vector addition of a learned or fixed bias term).

The “loss layer” (including calculating of a loss function) specifies how training penalizes the deviation between the predicted (output) and true labels and is normally the final layer of a neural network. Various loss functions appropriate for different tasks may be used. Softmax loss is used for predicting a single class of K mutually exclusive classes. Sigmoid cross-entropy loss is used for predicting K independent probability values in [0, 1]. Euclidean loss is used for regressing to real-valued labels.

As described above, FIG. 16 shows the data flow in a typical convolutional neural network. First, the input image is passed through convolutional layers and becomes abstracted to a feature map comprising several channels, corresponding to a number of filters in a set of learnable filters of this layer. Then, the feature map is subsampled using e.g. a pooling layer, which reduces the dimension of each channel in the feature map. Next, the data comes to another convolutional layer, which may have different numbers of output channels. As was mentioned above, the number of input channels and output channels are hyper-parameters of the layer. To establish connectivity of the network, those parameters need to be synchronized between two connected layers, such that the number of input channels for the current layers should be equal to the number of output channels of the previous layer. For the first layer which processes input data, e.g. an image, the number of input channels is normally equal to the number of channels of data representation, for instance 3 channels for RGB or YUV representation of images or video, or 1 channel for grayscale image or video representation.

### Estimating Activation Functions for Neural Network Layers

As discussed above, neural networks may include activation layers. The output of such activation layers may be determined by applying so-called activation functions. For example, several activation functions such as Sigmoid/Logistic, Hyperbolic Tangent, Exponential Linear Units, Softmax, Scaled Exponential Linear Unit and others may require deterministic behavior on different platforms. An estimate of such a non-linear activation function within at least one interval may be obtained analogously as discussed above for the CDF. The obtaining a CDF may be performed for other functions, such as activation functions that are applied in the processing by neural networks. The constraints applied in the approximation may correspond to the characteristics of the function to be approximated, such as monotony or continuousness or the like. In other words, the embodiments described herein used for obtaining a CDF for entropy coding and/or decoding can be equally applied for obtaining an activation function used in neural networks.

The activation function is approximated in a plurality of intervals. For each interval a subset of parameters is obtained. The subset of parameters defines a second order polynomial within said interval. The polynomial approximates the activation function within said interval. The second order polynomial fulfills a set of conditions. The set of conditions is adapted to the properties of the functions to be approximated, for example, monotonically increase/decrease, positive/negative derivative, discontinuities, or the like.

An estimate of an activation function which is applied in one or more layers of a neural network is obtained in at least one interval. Said at least one interval, which is included in a plurality of intervals, corresponds to a subrange of the value range of the activation function. The estimate of the activation function is obtained based on a function defined in the at least one interval. The function 1130 is defined in the at least one interval by parameters of a second order polynomial. The second order polynomial fulfills a set of conditions.

### Autoencoders and Unsupervised Learning

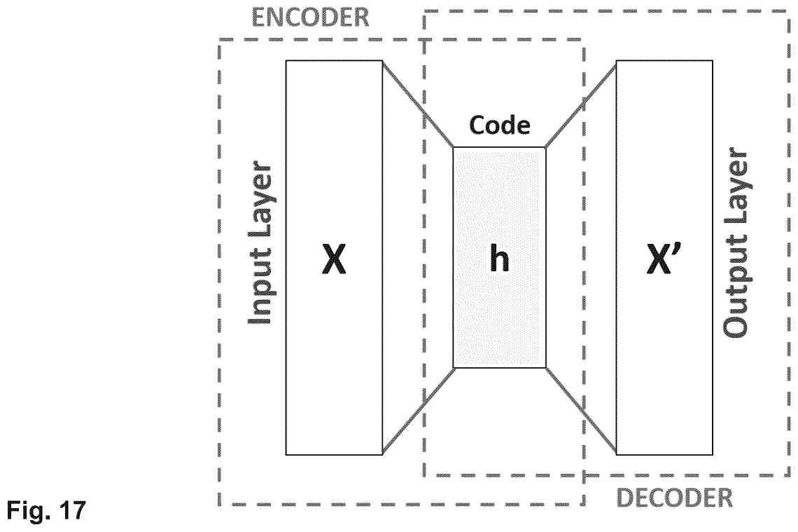

An autoencoder is a type of artificial neural network used to learn efficient data codings in an unsupervised manner. A schematic drawing thereof is shown in FIG. 17. The aim of an autoencoder is to learn a representation (encoding) for a set of data, typically for dimensionality reduction, by training the network to ignore signal “noise”. Along with the reduction side, a reconstructing side is learnt, where the autoencoder tries to generate from the reduced encoding a representation as close as possible to its original input, hence its name. In the simplest case, given one hidden layer, the encoder stage of an autoencoder takes the input x and maps it to h

h=σ(Wx+b).

This image h is usually referred to as code, latent variables, or latent representation. Here, σ is an element-wise activation function such as a sigmoid function or a rectified linear unit. W is a weight matrix b is a bias vector. Weights and biases are usually initialized randomly, and then updated iteratively during training through Backpropagation. After that, the decoder stage of the autoencoder maps h to the reconstruction x′ of the same shape as x:

x′=σ′(W′h′+b′)

where σ′, W′ and b′ for the decoder may be unrelated to the corresponding σ, W and b for the encoder.

Variational autoencoder models make strong assumptions concerning the distribution of latent variables. They use a variational approach for latent representation learning, which results in an additional loss component and an estimator for the training algorithm called the Stochastic Gradient Variational Bayes (SGVB) estimator. It assumes that the data is generated by a directed graphical model p_{θ}(x|h) and that the encoder is learning an approximation q_{ϕ}(h|x) to the posterior distribution p_{θ}(h|x) where ϕ and θ denote the parameters of the encoder (recognition model) and decoder (generative model) respectively. The probability distribution of the latent vector of a VAE typically matches that of the training data much closer than a standard autoencoder. The objective of VAE has the following form:

[symbol]

(ϕ,θ,x)=D_{KL}(q_{ϕ}(h|x)∥p_{θ}(h))−E_{q}_{_{ϕ}}(h|x)(log p_{θ}(x|h))

Here, D_{KL} stands for the Kullback-Leibler divergence. The prior over the latent variables is usually set to be the centered isotropic multivariate Gaussian p_{θ}(h)= [symbol] (0, I). Commonly, the shape of the variational and the likelihood distributions are chosen such that they are factorized Gaussians:

$${q}_{ϕ} ( h \vert x ) = 𝒩 ( ρ ( x ) , {ω}^{2} ( x ) I )$$

$${p}_{ϕ} ( x \vert h ) = 𝒩 ( μ ( h ) , {σ}^{2} ( h ) I )$$

where ρ(x) and ω²(x) are the encoder output, while ρ(h) and σ²(h) are the decoder outputs.

Recent progress in artificial neural networks area and especially in convolutional neural networks enables researchers' interest of applying neural networks based technologies to the task of image and video compression. For example, End-to-end Optimized Image Compression has been proposed, which uses a network based on a variational autoencoder.

Accordingly, data compression is considered as a fundamental and well-studied problem in engineering, and is commonly formulated with the goal of designing codes for a given discrete data ensemble with minimal entropy. The solution relies heavily on knowledge of the probabilistic structure of the data, and thus the problem is closely related to probabilistic source modeling. However, since all practical codes need to have finite entropy, continuous-valued data (such as vectors of image pixel intensities) need to be quantized to a finite set of discrete values, which introduces an error.

In this context, known as the lossy compression problem, one needs to trade off two competing costs: the entropy of the discretized representation (rate) and the error arising from the quantization (distortion). Different compression applications, such as data storage or transmission over limited-capacity channels, demand different rate-distortion trade-offs.

Joint optimization of rate and distortion is difficult. Without further constraints, the general problem of optimal quantization in high-dimensional spaces is intractable. For this reason, most existing image compression methods operate by linearly transforming the data vector into a suitable continuous-valued representation, quantizing its elements independently, and then encoding the resulting discrete representation using a lossless entropy code. This scheme is called transform coding due to the central role of the transformation.

For example, JPEG uses a discrete cosine transform on blocks of pixels, and JPEG 2000 uses a multi-scale orthogonal wavelet decomposition. Typically, the three components of transform coding methods—transform, quantizer, and entropy code—are separately optimized (often through manual parameter adjustment). Modern video compression standards like HEVC, VVC and EVC also use transformed representation to code residual signal after prediction. The several transforms are used for that purpose such as discrete cosine and sine transforms (DCT, DST), as well as low frequency non-separable manually optimized transforms (LFNST).

### Variational Image Compression

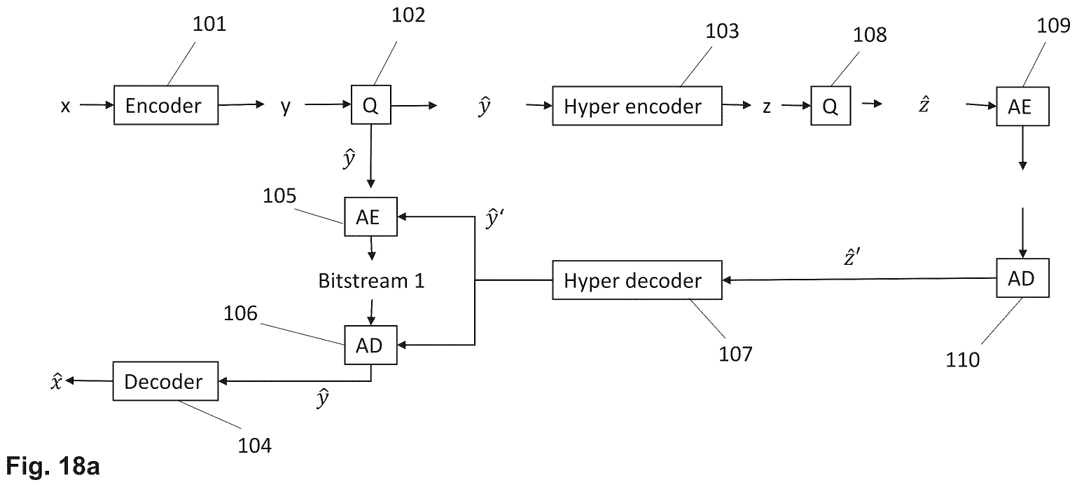

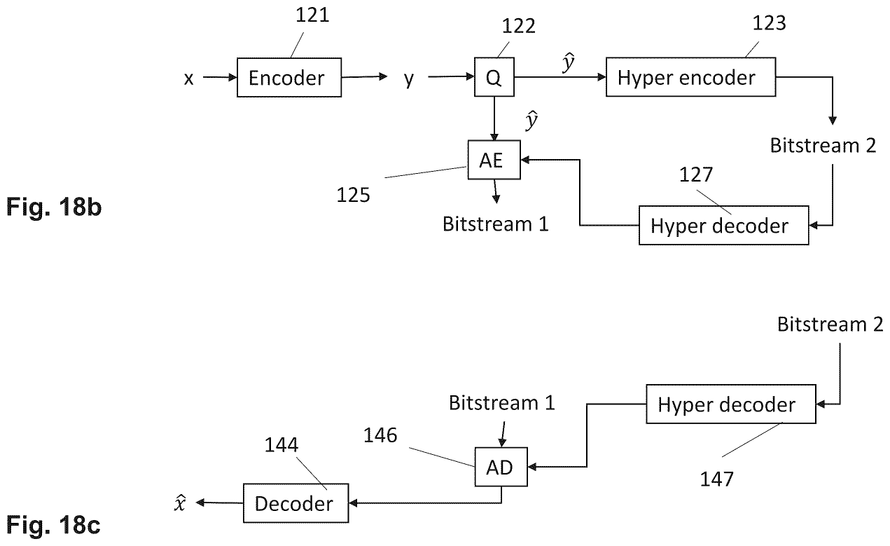

Variable Auto-Encoder (VAE) framework can be considered as a nonlinear transforming coding model. The transforming process can be mainly divided into four parts. This is exemplified in FIG. 18a showing a VAE framework.

The transforming process can be mainly divided into four parts: FIG. 18a exemplifies the VAE framework. In FIG. 18a, the encoder 101 maps an input image x into a latent representation (denoted by y) via the function y=f (x). This latent representation may also be referred to as a part of or a point within a “latent space” in the following. The function f( ) is a transformation function that converts the input signal x into a more compressible representation y. The quantizer 102 transforms the latent representation y into the quantized latent representation 9 with (discrete) values by ŷ=Q(y), with Q representing the quantizer function. The entropy model, or the hyper encoder/decoder (also known as hyperprior) 103 estimates the distribution of the quantized latent representation ŷ to get the minimum rate achievable with a lossless entropy source coding.

The latent space can be understood as a representation of compressed data in which similar data points are closer together in the latent space. Latent space is useful for learning data features and for finding simpler representations of data for analysis. The quantized latent representation T, ŷ and the side information \hat{z} of the hyperprior 3 are included into a bitstream 2 (are binarized) using arithmetic coding (AE). Furthermore, a decoder 104 is provided that transforms the quantized latent representation to the reconstructed image \hat{x}, x\hat{=}g(ŷ). The signal \hat{x} is the estimation of the input image x. It is desirable that x is as close to \hat{x} as possible, in other words the reconstruction quality is as high as possible. However, the higher the similarity between \hat{x} and x, the higher the amount of side information necessary to be transmitted. The side information includes bitstream1 and bitstream2 shown in FIG. 18a, which are generated by the encoder and transmitted to the decoder. Normally, the higher the amount of side information, the higher the reconstruction quality. However, a high amount of side information means that the compression ratio is low. Therefore, one purpose of the system described in FIG. 18a is to balance the reconstruction quality and the amount of side information conveyed in the bitstream.

In FIG. 18a the component AE 105 is the Arithmetic Encoding module, which converts samples of the quantized latent representation ŷ and the side information \hat{z} into a binary representation bitstream 1. The samples of ŷ and \hat{z} might for example comprise integer or floating point numbers. One purpose of the arithmetic encoding module is to convert (via the process of binarization) the sample values into a string of binary digits (which is then included in the bitstream that may comprise further portions corresponding to the encoded image or further side information).

The arithmetic decoding (AD) 106 is the process of reverting the binarization process, where binary digits are converted back to sample values. The arithmetic decoding is provided by the arithmetic decoding module 106.

It is noted that the present disclosure is not limited to this particular framework. Moreover, the present disclosure is not restricted to image or video compression, and can be applied to object detection, image generation, and recognition systems as well.

In FIG. 18a there are two sub networks concatenated to each other. A subnetwork in this context is a logical division between the parts of the total network. For example, in FIG. 18a the modules 101, 102, 104, 105 and 106 are called the “Encoder/Decoder” subnetwork. The “Encoder/Decoder” subnetwork is responsible for encoding (generating) and decoding (parsing) of the first bitstream “bitstream1”. The second network in FIG. 18a comprises modules 103, 108, 109, 110 and 107 and is called “hyper encoder/decoder” subnetwork. The second subnetwork is responsible for generating the second bitstream “bitstream2”. The purposes of the two subnetworks are different.

The first subnetwork is responsible for:
the transformation 101 of the input image x into its latent representation y (which is easier to compress that x),
quantizing 102 the latent representation y into a quantized latent representation ŷ,
compressing the quantized latent representation ŷ using the AE by the arithmetic encoding module 105 to obtain bitstream “bitstream 1”,”.
parsing the bitstream 1 via AD using the arithmetic decoding module 106, and
reconstructing 104 the reconstructed image (\hat{x}) using the parsed data.

The purpose of the second subnetwork is to obtain statistical properties (e.g. mean value, variance and correlations between samples of bitstream 1) of the samples of “bitstream1”, such that the compressing of bitstream 1 by first subnetwork is more efficient. The second subnetwork generates a second bitstream “bitstream2”, which comprises the said information (e.g. mean value, variance and correlations between samples of bitstream1).

The second network includes an encoding part which comprises transforming 103 of the quantized latent representation ŷ into side information z, quantizing the side information z into quantized side information \hat{z}, and encoding (e.g. binarizing) 109 the quantized side information \hat{z} into bitstream2. In this example, the binarization is performed by an arithmetic encoding (AE). A decoding part of the second network includes arithmetic decoding (AD) 110, which transforms the input bitstream2 into decoded quantized side information \hat{z}′. The \hat{z}′ might be identical to \hat{z}, since the arithmetic encoding end decoding operations are lossless compression methods. The decoded quantized side information \hat{z}′ is then transformed 107 into decoded side information ŷ′. ŷ′ represents the statistical properties of ŷ (e.g. mean value of samples of ŷ, or the variance of sample values or like). The decoded latent representation ŷ′ is then provided to the above-mentioned Arithmetic Encoder 105 and Arithmetic Decoder 106 to control the probability model of ŷ.

The FIG. 18a describes an example of VAE (variational auto encoder), details of which might be different in different implementations. For example in an exemplary implementation additional components might be present to more efficiently obtain the statistical properties of the samples of bitstream 1. In one such implementation a context modeler might be present, which targets extracting cross-correlation information of the bitstream 1. The statistical information provided by the second subnetwork might be used by AE (arithmetic encoder) 105 and AD (arithmetic decoder) 106 components.

FIG. 18a depicts the encoder and decoder in a single figure. As is clear to those skilled in the art, the encoder and the decoder may be, and very often are, embedded in mutually different devices.

FIG. 18b depicts the encoder and FIG. 18c depicts the decoder components of the VAE framework in isolation. As input, the encoder receives, according to some embodiments, a picture. The input picture may include one or more channels, such as color channels or other kind of channels, e.g. depth channel or motion information channel, or the like. The output of the encoder (as shown in FIG. 18b) is a bitstream1 and a bitstream2. The bitstream1 is the output of the first sub-network of the encoder and the bitstream2 is the output of the second subnetwork of the encoder.

Similarly, in FIG. 18c, the two bitstreams, bitstream1 and bitstream2, are received as input and \hat{z}, which is the reconstructed (decoded) image, is generated at the output. As indicated above, the VAE can be split into different logical units that perform different actions. This is exemplified in FIGS. 18b and 18c so that FIG. 18b depicts components that participate in the encoding of a signal, like a video and provided encoded information. This encoded information is then received by the decoder components depicted in FIG. 18c for encoding, for example. It is noted that the components of the encoder and decoder denoted with numerals 12x and 14x may correspond in their function to the components referred to above in FIG. 18a and denoted with numerals 10x.

As is seen in FIG. 18b, the encoder comprises the encoder 121 that transforms an input x into a signal y which is then provided to the quantizer 322. The quantizer 122 provides information to the arithmetic encoding module 125 and the hyper encoder 123. The hyper encoder 123 provides the bitstream2 already discussed above to the hyper decoder 147 that in turn provides the information to the arithmetic encoding module 105 (125).

The output of the arithmetic encoding module is the bitstream1. The bitstream1 and bitstream2 are the output of the encoding of the signal, which are then provided (transmitted) to the decoding process. Although the unit 101 (121) is called “encoder”, it is also possible to call the complete subnetwork described in FIG. 18b as “encoder”. The process of encoding in general means the unit (module) that converts an input to an encoded (e.g. compressed) output. It can be seen from FIG. 18b, that the unit 121 can be actually considered as a core of the whole subnetwork, since it performs the conversion of the input x into y, which is the compressed version of the x. The compression in the encoder 121 may be achieved, e.g. by applying a neural network, or in general any processing network with one or more layers. In such network, the compression may be performed by cascaded processing including downsampling which reduces size and/or number of channels of the input. Thus, the encoder may be referred to, e.g. as a neural network (NN) based encoder, or the like.

The remaining parts in the figure (quantization unit, hyper encoder, hyper decoder, arithmetic encoder/decoder) are all parts that either improve the efficiency of the encoding process or are responsible for converting the compressed output y into a series of bits (bitstream). Quantization may be provided to further compress the output of the NN encoder 121 by a lossy compression. The AE 125 in combination with the hyper encoder 123 and hyper decoder 127 used to configure the AE 125 may perform the binarization which may further compress the quantized signal by a lossless compression. Therefore, it is also possible to call the whole subnetwork in FIG. 18b an “encoder”.

A majority of Deep Learning (DL) based image/video compression systems reduce dimensionality of the signal before converting the signal into binary digits (bits). In the VAE framework for example, the encoder, which is a non-linear transform, maps the input image x into y, where y has a smaller width and height than x. Since the y has a smaller width and height, hence a smaller size, the (size of the) dimension of the signal is reduced, and, hence, it is easier to compress the signal y. It is noted that in general, the encoder does not necessarily need to reduce the size in both (or in general all) dimensions. Rather, some exemplary implementations may provide an encoder which reduces size only in one (or in general a subset of) dimension.

In J. Balle, L. Valero Laparra, and E. P. Simoncelli (2015). “Density Modeling of Images Using a Generalized Normalization Transformation”, In: arXiv e-prints, Presented at the 4th Int. Conf. for Learning Representations, 2016 (referred to in the following as “Balle”) the authors proposed a framework for end-to-end optimization of an image compression model based on nonlinear transforms. The authors optimize for Mean Squared Error (MSE), but use a more flexible transforms built from cascades of linear convolutions and nonlinearities. Authors use a generalized divisive normalization (GDN) joint nonlinearity that is inspired by models of neurons in biological visual systems, and has proven effective in Gaussianizing image densities. This cascaded transformation is followed by uniform scalar quantization (i.e., each element is rounded to the nearest integer), which effectively implements a parametric form of vector quantization on the original image space. The compressed image is reconstructed from these quantized values using an approximate parametric nonlinear inverse transform.

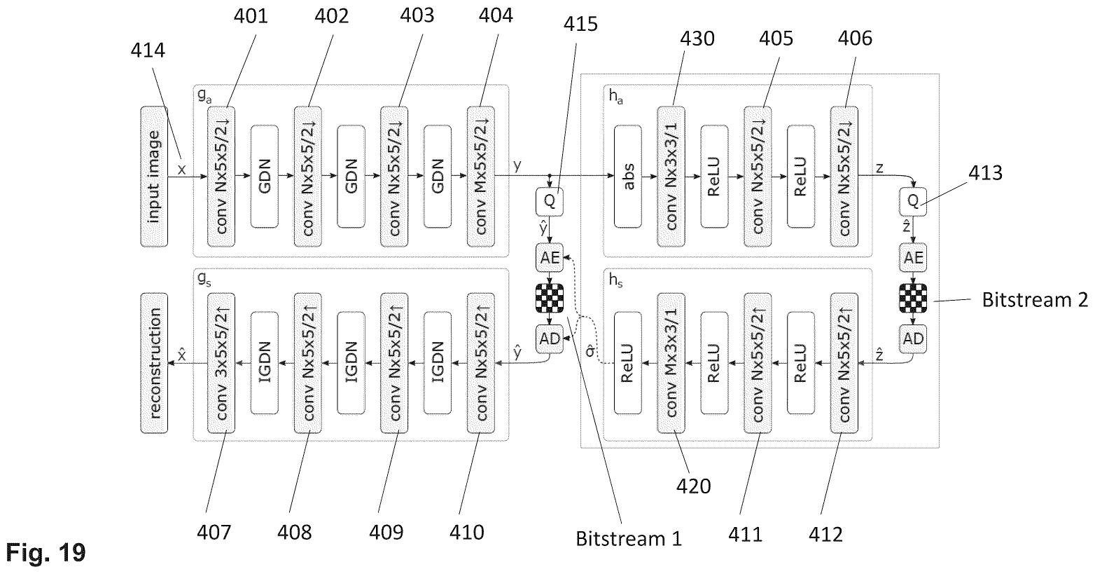

Such example of the VAE framework is shown in FIG. 19, and it utilizes 6 downsampling layers that are marked with 401 to 406. The network architecture includes a hyperprior model. The left side (gₐ, gₛ) shows an image autoencoder architecture, the right side (hₐ, hₛ) corresponds to the autoencoder implementing the hyperprior. The factorized-prior model uses the identical architecture for the analysis and synthesis transforms gₐ and gₛ. Q represents quantization, and AE, AD represent arithmetic encoder and arithmetic decoder, respectively. The encoder subjects the input image x to gₐ, yielding the responses y (latent representation) with spatially varying standard deviations. The encoding gₐ includes a plurality of convolution layers with subsampling and, as an activation function, generalized divisive normalization (GDN).

The responses are fed into hₐ, summarizing the distribution of standard deviations in z. z is then quantized, compressed, and transmitted as side information. The encoder then uses the quantized vector \hat{z} to estimate \hat{σ}, the spatial distribution of standard deviations which is used for obtaining probability values (or frequency values) for arithmetic coding (AE), and uses it to compress and transmit the quantized image representation ŷ (or latent representation). The decoder first recovers 2 from the compressed signal. It then uses hₛ to obtain ŷ, which provides it with the correct probability estimates to successfully recover ŷ as well. It then feeds ŷ into gₛ to obtain the reconstructed image.

The layers that include downsampling is indicated with the downward arrow in the layer description. The layer description “Conv N×5×5/2↑” means that the layer is a convolution layer, with N channels and the convolution kernel is 5×5 in size. As stated, the 2↑ means that a downsampling with a factor of 2 is performed in this layer. Downsampling by a factor of 2 results in one of the dimensions of the input signal being reduced by half at the output. In FIG. 19, the 2↑ indicates that both width and height of the input image is reduced by a factor of 2. Since there are 6 downsampling layers, if the width and height of the input image 414 (also denoted with x) is given by w and h, the output signal z\hat{ }413 is has width and height equal to w/64 and h/64 respectively. Modules denoted by AE and AD are arithmetic encoder and arithmetic decoder, which are explained with reference to FIGS. 18a to 18c. The arithmetic encoder and decoder are implementations of entropy coding. AE and AD can be replaced by other means of entropy coding. In information theory, an entropy encoding is a lossless data compression scheme that is used to convert the values of a symbol into a binary representation which is a revertible process. Also, the “Q” in the figure corresponds to the quantization operation that was also referred to above in relation to FIG. 19 and is further explained above in the section “Quantization”. Also, the quantization operation and a corresponding quantization unit as part of the component 413 or 415 is not necessarily present and/or can be replaced with another unit.

In FIG. 19, there is also shown the decoder comprising upsampling layers 407 to 412. A further layer 420 is provided between the upsampling layers 411 and 410 in the processing order of an input that is implemented as convolutional layer but does not provide an upsampling to the input received. A corresponding convolutional layer 430 is also shown for the decoder. Such layers can be provided in NNs for performing operations on the input that do not alter the size of the input but change some characteristics. However, it is not necessary that such a layer is provided.

When seen in the processing order of bitstream2 through the decoder, the upsampling layers are run through in reverse order, i.e. from upsampling layer 412 to upsampling layer 407. Each upsampling layer is shown here to provide an upsampling with an upsampling ratio of 2, which is indicated by the ↓. It is, of course, not necessarily the case that all upsampling layers have the same upsampling ratio and also other upsampling ratios like 3, 4, 8 or the like may be used. The layers 407 to 412 are implemented as convolutional layers (conv). As they may be intended to provide an operation on the input that is reverse to that of the encoder, the upsampling layers may apply a deconvolution operation to the input received so that its size is increased by a factor corresponding to the upsampling ratio. However, the present disclosure is not generally limited to deconvolution and the upsampling may be performed in any other manner such as by bilinear interpolation between two neighboring samples, or by nearest neighbor sample copying, or the like.

In the first subnetwork, some convolutional layers (401 to 403) are followed by generalized divisive normalization (GDN) at the encoder side and by the inverse GDN (IGDN) at the decoder side. In the second subnetwork, the activation function applied is ReLu. It is noted that the present disclosure is not limited to such implementation and in general, other activation functions may be used instead of GDN or ReLu.

### Cloud Solutions for Machine Tasks

The Video Coding for Machines (VCM) is another computer science direction being popular nowadays. The main idea behind this approach is to transmit the coded representation of image or video information targeted to further processing by computer vision (CV) algorithms, like object segmentation, detection and recognition. In contrast to traditional image and video coding targeted to human perception the quality characteristic is the performance of computer vision task, e.g. object detection accuracy, rather than reconstructed quality.

Video Coding for Machines is also referred to as collaborative intelligence and it is a relatively new paradigm for efficient deployment of deep neural networks across the mobile-cloud infrastructure. By dividing the network between the mobile and the cloud, it is possible to distribute the computational workload such that the overall energy and/or latency of the system is minimized. In general, the collaborative intelligence is a paradigm where processing of a neural network is distributed between two or more different computation nodes; for example devices, but in general, any functionally defined nodes. Here, the term “node” does not refer to the above-mentioned neural network nodes. Rather the (computation) nodes here refer to (physically or at least logically) separate devices/modules, which implement parts of the neural network. Such devices may be different servers, different end user devices, a mixture of servers and/or user devices and/or cloud and/or processor or the like. In other words, the computation nodes may be considered as nodes belonging to the same neural network and communicating with each other to convey coded data within/for the neural network. For example, in order to be able to perform complex computations, one or more layers may be executed on a first device and one or more layers may be executed in another device. However, the distribution may also be finer and a single layer may be executed on a plurality of devices. In this disclosure, the term “plurality” refers to two or more. In some existing solution, a part of a neural network functionality is executed in a device (user device or edge device or the like) or a plurality of such devices and then the output (feature map) is passed to a cloud. A cloud is a collection of processing or computing systems that are located outside the device, which is operating the part of the neural network. The notion of collaborative intelligence has been extended to model training as well. In this case, data flows both ways: from the cloud to the mobile during back-propagation in training, and from the mobile to the cloud during forward passes in training, as well as inference.

Some works presented semantic image compression by encoding deep features and then reconstructing the input image from them. The compression based on uniform quantization was shown, followed by context-based adaptive arithmetic coding (CABAC) from H.264. In some scenarios, it may be more efficient, to transmit from the mobile part to the cloud an output of a hidden layer (a deep feature map), rather than sending compressed natural image data to the cloud and perform the object detection using reconstructed images. The efficient compression of feature maps benefits the image and video compression and reconstruction both for human perception and for machine vision. Entropy coding methods, e.g. arithmetic coding is a popular approach to compression of deep features (i.e. feature maps).

Nowadays, video content contributes to more than 80% internet traffic, and the percentage is expected to increase even further. Therefore, it is critical to build an efficient video compression system and generate higher quality frames at given bandwidth budget. In addition, most video related computer vision tasks such as video object detection or video object tracking are sensitive to the quality of compressed videos, and efficient video compression may bring benefits for other computer vision tasks. Meanwhile, the techniques in video compression are also helpful for action recognition and model compression. However, in the past decades, video compression algorithms rely on hand-crafted modules, e.g., block based motion estimation and Discrete Cosine Transform (DCT), to reduce the redundancies in the video sequences, as mentioned above. Although each module is well designed, the whole compression system is not end-to-end optimized. It is desirable to further improve video compression performance by jointly optimizing the whole compression system.

### End-to-End Image or Video Compression

DNN based image compression methods can exploit large scale end-to-end training and highly non-linear transform, which are not used in the traditional approaches. However, it is non-trivial to directly apply these techniques to build an end-to-end learning system for video compression. First, it remains an open problem to learn how to generate and compress the motion information tailored for video compression. Video compression methods heavily rely on motion information to reduce temporal redundancy in video sequences.

A straightforward solution is to use the learning based optical flow to represent motion information. However, current learning based optical flow approaches aim at generating flow fields as accurate as possible. The precise optical flow is often not optimal for a particular video task. In addition, the data volume of optical flow increases significantly when compared with motion information in the traditional compression systems and directly applying the existing compression approaches to compress optical flow values will significantly increase the number of bits required for storing motion information. Second, it is unclear how to build a DNN based video compression system by minimizing the rate-distortion based objective for both residual and motion information. Rate-distortion optimization (RDO) aims at achieving higher quality of reconstructed frame (i.e., less distortion) when the number of bits (or bit rate) for compression is given. RDO is important for video compression performance. In order to exploit the power of end-to-end training for learning based compression system, the RDO strategy is required to optimize the whole system.

In Guo Lu, Wanli Ouyang, Dong Xu, Xiaoyun Zhang, Chunlei Cai, Zhiyong Gao; “DVC: An End-to-end Deep Video Compression Framework”. Proceedings of the IEEE CVF Conference on Computer Vision and Pattern Recognition (CVPR), 2019, pp. 11006-11015, authors proposed the end-to-end deep video compression (DVC) model that jointly learns motion estimation, motion compression, and residual coding.

Such encoder is illustrated in FIG. 6A. In particular, FIG. 6A shows an overall structure of end-to-end trainable video compression framework. In order to compress motion information, a CNN was designated to transform the optical flow to the corresponding representations suitable for better compression. An auto-encoder style network is used to compress the optical flow. The motion vectors (MV) compression network is shown in FIG. 6B. The network architecture is somewhat similar to the ga/gs of FIG. 4. In particular, the optical flow is fed into a series of convolution operation and nonlinear transform including GDN and IGDN. The number of output channels for convolution (deconvolution) is 128 except for the last deconvolution layer, which is equal to 2. Given optical flow with the size of M×N×2, the MV encoder will generate the motion representation with the size of M/16×N/16×128. Then motion representation is quantized, entropy coded and sent to bitstream. The MV decoder receives the quantized representation and reconstruct motion information using MV encoder.

FIG. 6C shows a structure of the motion compensation part. Here, using previous reconstructed frame xₜ₋₁ and reconstructed motion information, the warping unit generates the warped frame (normally, with help of interpolation filter such as bi-linear interpolation filter). Then a separate CNN with three inputs generates the predicted picture. The architecture of the motion compensation CNN is also shown in FIG. 6C.

The residual information between the original frame and the predicted frame is encoded by the residual encoder network. A highly non-linear neural network is used to transform the residuals to the corresponding latent representation. Compared with discrete cosine transform in the traditional video compression system, this approach can better exploit the power of non-linear transform and achieve higher compression efficiency.

From above overview it can be seen that CNN based architecture can be applied both for image and video compression, considering different parts of video framework including motion estimation, motion compensation and residual coding. Entropy coding is popular method used for data compression, which is widely adopted by the industry and is also applicable for feature map compression either for human perception or for computer vision tasks.

Implementation within Picture Coding

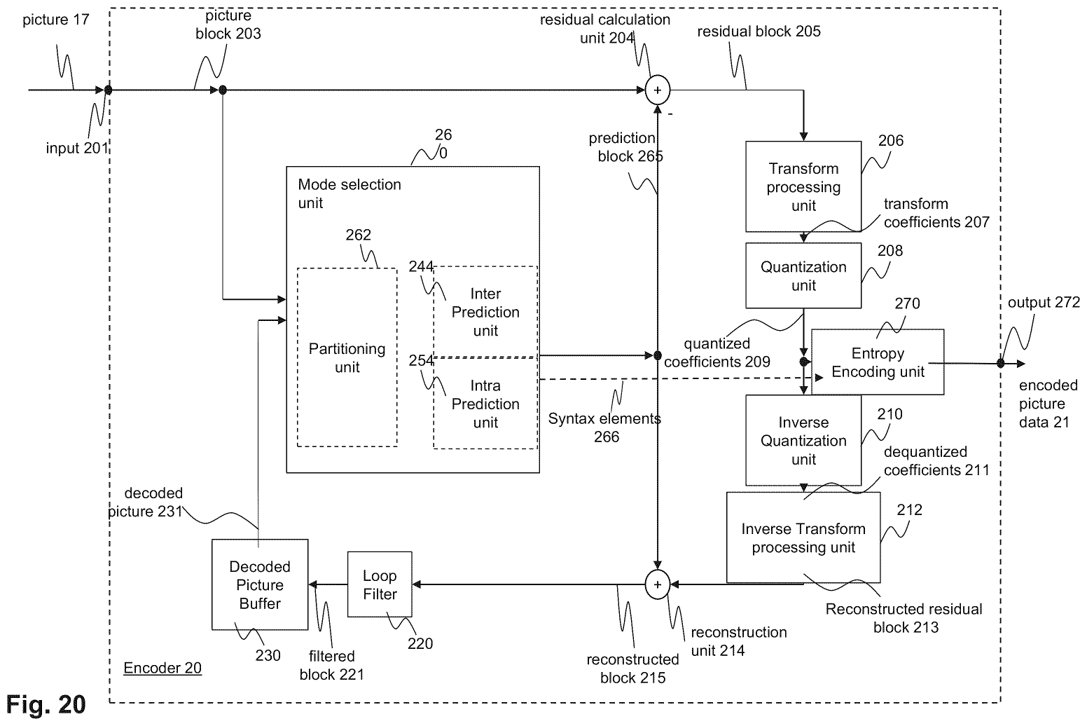

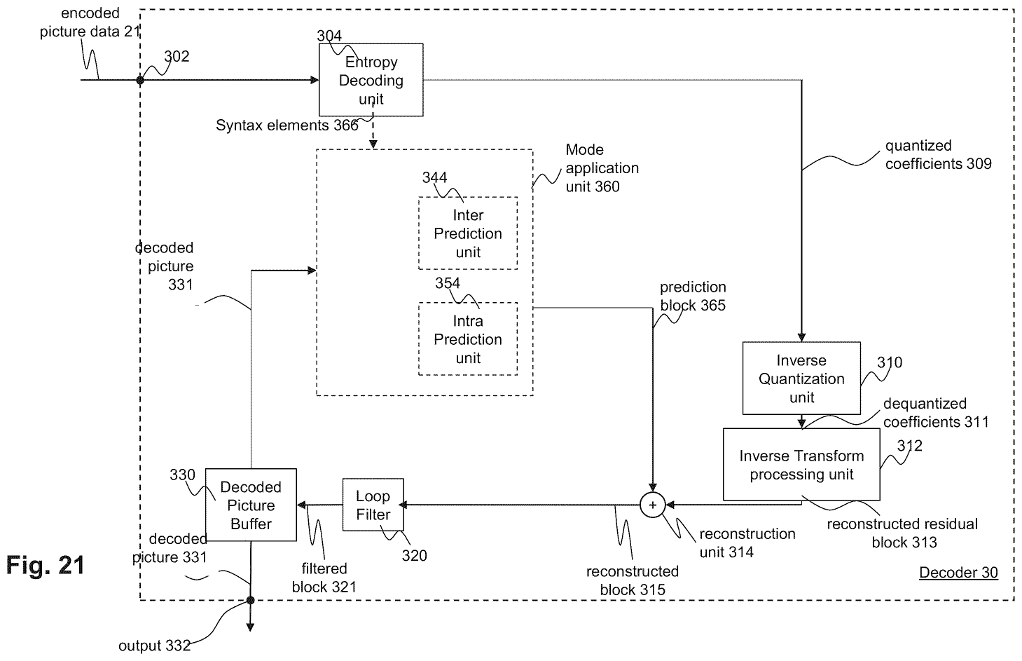

One possible deployment can be seen in FIGS. 20 and 21.

FIG. 20 shows a schematic block diagram of an example video encoder 20 that is configured to implement the techniques of the present application. In the example of FIG. 20, the video encoder 20 comprises an input 201 (or input interface 201), a residual calculation unit 204, a transform processing unit 206, a quantization unit 208, an inverse quantization unit 210, and inverse transform processing unit 212, a reconstruction unit 214, a loop filter unit 220, a decoded picture buffer (DPB) 230, a mode selection unit 260, an entropy encoding unit 270 and an output 272 (or output interface 272). The entropy coding 270 may implement the arithmetic coding methods or apparatuses as described above.

The mode selection unit 260 may include an inter prediction unit 244, an intra prediction unit 254 and a partitioning unit 262. Inter prediction unit 244 may include a motion estimation unit and a motion compensation unit (not shown). A video encoder 20 as shown in FIG. 20 may also be referred to as hybrid video encoder or a video encoder according to a hybrid video codec.

The encoder 20 may be configured to receive, e.g. via input 201, a picture 17 (or picture data 17), e.g. picture of a sequence of pictures forming a video or video sequence. The received picture or picture data may also be a pre-processed picture 19 (or pre-processed picture data 19). For sake of simplicity the following description refers to the picture 17. The picture 17 may also be referred to as current picture or picture to be coded (in particular in video coding to distinguish the current picture from other pictures, e.g. previously encoded and/or decoded pictures of the same video sequence, i.e. the video sequence which also comprises the current picture).

A (digital) picture is or can be regarded as a two-dimensional array or matrix of samples with intensity values. A sample in the array may also be referred to as pixel (short form of picture element) or a pel. The number of samples in horizontal and vertical direction (or axis) of the array or picture define the size and/or resolution of the picture. For representation of color, typically three color components are employed, i.e. the picture may be represented or include three sample arrays. In RGB format or color space a picture comprises a corresponding red, green and blue sample array. However, in video coding each pixel is typically represented in a luminance and chrominance format or color space, e.g. YCbCr, which comprises a luminance component indicated by Y (sometimes also L is used instead) and two chrominance components indicated by Cb and Cr. The luminance (or short luma) component Y represents the brightness or grey level intensity (e.g. like in a grey-scale picture), while the two chrominance (or short chroma) components Cb and Cr represent the chromaticity or color information components. Accordingly, a picture in YCbCr format comprises a luminance sample array of luminance sample values (Y), and two chrominance sample arrays of chrominance values (Cb and Cr). Pictures in RGB format may be converted or transformed into YCbCr format and vice versa, the process is also known as color transformation or conversion. If a picture is monochrome, the picture may comprise only a luminance sample array. Accordingly, a picture may be, for example, an array of luma samples in monochrome format or an array of luma samples and two corresponding arrays of chroma samples in 4:2:0, 4:2:2, and 4:4:4 color format.

Embodiments of the video encoder 20 may comprise a picture partitioning unit (not depicted in FIG. 20) configured to partition the picture 17 into a plurality of (typically non-overlapping) picture blocks 203. These blocks may also be referred to as root blocks, macro blocks (H.264/AVC) or coding tree blocks (CTB) or coding tree units (CTU) (H.265/HEVC and VVC). The picture partitioning unit may be configured to use the same block size for all pictures of a video sequence and the corresponding grid defining the block size, or to change the block size between pictures or subsets or groups of pictures, and partition each picture into the corresponding blocks. The abbreviation AVC stands for Advanced Video Coding.

In further embodiments, the video encoder may be configured to receive directly a block 203 of the picture 17, e.g. one, several or all blocks forming the picture 17. The picture block 203 may also be referred to as current picture block or picture block to be coded.

Like the picture 17, the picture block 203 again is or can be regarded as a two-dimensional array or matrix of samples with intensity values (sample values), although of smaller dimension than the picture 17. In other words, the block 203 may comprise, e.g., one sample array (e.g. a luma array in case of a monochrome picture 17, or a luma or chroma array in case of a color picture) or three sample arrays (e.g. a luma and two chroma arrays in case of a color picture 17) or any other number and/or kind of arrays depending on the color format applied. The number of samples in horizontal and vertical direction (or axis) of the block 203 define the size of block 203. Accordingly, a block may, for example, an M×N (M-column by N-row) array of samples, or an M×N array of transform coefficients.

Embodiments of the video encoder 20 as shown in FIG. 20 may be configured to encode the picture 17 block by block, e.g. the encoding and prediction is performed per block 203.

Embodiments of the video encoder 20 as shown in FIG. 20 may be further configured to partition and/or encode the picture using slices (also referred to as video slices), wherein a picture may be partitioned into or encoded using one or more slices (typically non-overlapping), and each slice may comprise one or more blocks (e.g. CTUs).

Embodiments of the video encoder 20 as shown in FIG. 20 may be further configured to partition and/or encode the picture using tile groups (also referred to as video tile groups) and/or tiles (also referred to as video tiles), wherein a picture may be partitioned into or encoded using one or more tile groups (typically non-overlapping), and each tile group may comprise, e.g. one or more blocks (e.g. CTUs) or one or more tiles, wherein each tile, e.g. may be of rectangular shape and may comprise one or more blocks (e.g. CTUs), e.g. complete or fractional blocks.

FIG. 21 shows an example of a video decoder 30 that is configured to implement the techniques of this present application. The video decoder 30 is configured to receive encoded picture data 21 (e.g. encoded bitstream 21), e.g. encoded by encoder 20, to obtain a decoded picture 331. The encoded picture data or bitstream comprises information for decoding the encoded picture data, e.g. data that represents picture blocks of an encoded video slice (and/or tile groups or tiles) and associated syntax elements.

The entropy decoding unit 304 is configured to parse the bitstream 21 (or in general encoded picture data 21) and perform, for example, entropy decoding to the encoded picture data 21 to obtain, e.g., quantized coefficients 309 and/or decoded coding parameters (not shown in FIG. 21), e.g. any or all of inter prediction parameters (e.g. reference picture index and motion vector), intra prediction parameter (e.g. intra prediction mode or index), transform parameters, quantization parameters, loop filter parameters, and/or other syntax elements. Entropy decoding unit 304 maybe configured to apply the decoding algorithms or schemes corresponding to the encoding schemes as described with regard to the entropy encoding unit 270 of the encoder 20. Entropy decoding unit 304 may be further configured to provide inter prediction parameters, intra prediction parameter and/or other syntax elements to the mode application unit 360 and other parameters to other units of the decoder 30. Video decoder 30 may receive the syntax elements at the video slice level and/or the video block level. In addition or as an alternative to slices and respective syntax elements, tile groups and/or tiles and respective syntax elements may be received and/or used. The entropy decoding may implement any of the above mentioned arithmetic decoding methods or apparatuses.

The reconstruction unit 314 (e.g. adder or summer 314) may be configured to add the reconstructed residual block 313, to the prediction block 365 to obtain a reconstructed block 315 in the sample domain, e.g. by adding the sample values of the reconstructed residual block 313 and the sample values of the prediction block 365.

Embodiments of the video decoder 30 as shown in FIG. 21 may be configured to partition and/or decode the picture using slices (also referred to as video slices), wherein a picture may be partitioned into or decoded using one or more slices (typically non-overlapping), and each slice may comprise one or more blocks (e.g. CTUs).

Embodiments of the video decoder 30 as shown in FIG. 21 may be configured to partition and/or decode the picture using tile groups (also referred to as video tile groups) and/or tiles (also referred to as video tiles), wherein a picture may be partitioned into or decoded using one or more tile groups (typically non-overlapping), and each tile group may comprise, e.g. one or more blocks (e.g. CTUs) or one or more tiles, wherein each tile, e.g. may be of rectangular shape and may comprise one or more blocks (e.g. CTUs), e.g. complete or fractional blocks.

Other variations of the video decoder 30 can be used to decode the encoded picture data 21. For example, the decoder 30 can produce the output video stream without the loop filtering unit 320. For example, a non-transform based decoder 30 can inverse-quantize the residual signal directly without the inverse-transform processing unit 312 for certain blocks or frames. In another implementation, the video decoder 30 can have the inverse-quantization unit 310 and the inverse-transform processing unit 312 combined into a single unit.

It should be understood that, in the encoder 20 and the decoder 30, a processing result of a current step may be further processed and then output to the next step. For example, after interpolation filtering, motion vector derivation or loop filtering, a further operation, such as Clip or shift, may be performed on the processing result of the interpolation filtering, motion vector derivation or loop filtering.

One or more blocks within the exemplary scheme of the hybrid encoder explained above with reference to FIGS. 20 and 21 may be implemented by a processing by neural networks. For example, the inter prediction unit 244 and/or the intra prediction unit 254 may involve processing by neural networks.

### Implementations in Hardware and Software

Some further implementations in hardware and software are described in the following.

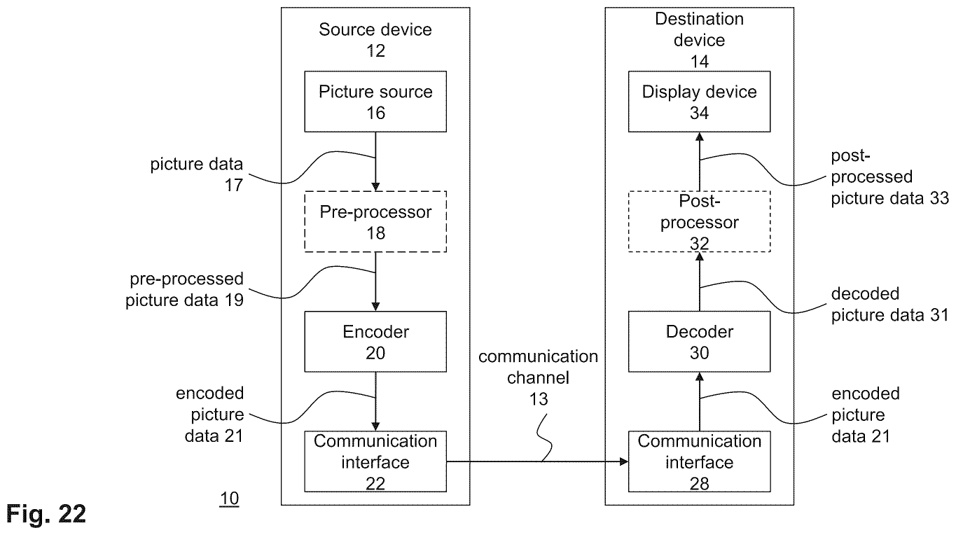

Any of the encoding devices described in the following with references to FIGS. 22-25 may provide means in order to carry out the entropy encoding data into a bitstream. A processing circuitry within any of these exemplary devices is configured to obtain an estimate of a cumulative distribution function and entropy encode data applying a probability model based on the obtained CDF in the at least one interval according to the method described above.

The decoding devices in any of FIGS. 22-25, may contain a processing circuitry, which is adapted to perform the decoding method. The method as described above comprises obtain an estimate of a cumulative distribution function, CDF, for at least one interval out of a plurality of predetermined intervals, wherein the CDF is obtained based on a function defined in the at least one interval by parameters of a second order polynomial, and said second order polynomial fulfills a set of conditions, and entropy decode said data applying a probability model based on the obtained CDF in the at least one interval.

Any of the devices in any of FIGS. 22-25 or another device, may contain a processing circuitry configured to obtain a subset of a set of parameters defining a second order polynomial within an interval, the second order polynomial approximating the CDF, wherein said polynomial fulfills a set conditions for an interval within a plurality of predetermined intervals.

In the following embodiments of a video coding system 10, a video encoder 20 and a video decoder 30 are described based on FIG. 22 to 25, with reference to the above mentioned FIGS. 20 and 21 or other encoder and decoder such as a neural network based encoder and decoder.

FIG. 22 is a schematic block diagram illustrating an example coding system, e.g. a video, image, audio, and/or other coding system (or short coding system) that may utilize techniques of this present application. Video encoder 20 (or short encoder 20) and video decoder 30 (or short decoder 30) of video coding system 10 represent examples of devices that may be configured to perform techniques in accordance with various examples described in the present application. For example, the video coding and decoding may employ neural network such which may be distributed and which may apply the above-mentioned bitstream parsing and/or bitstream generation to convey feature maps between the distributed computation nodes (two or more).

As shown in FIG. 22, the coding system 10 comprises a source device 12 configured to provide encoded picture data 21 e.g. to a destination device 14 for decoding the encoded picture data 13.

The source device 12 comprises an encoder 20, and may additionally, i.e. optionally, comprise a picture source 16, a pre-processor (or pre-processing unit) 18, e.g. a picture pre-processor 18, and a communication interface or communication unit 22.

The picture source 16 may comprise or be any kind of picture capturing device, for example a camera for capturing a real-world picture, and/or any kind of a picture generating device, for example a computer-graphics processor for generating a computer animated picture, or any kind of other device for obtaining and/or providing a real-world picture, a computer generated picture (e.g. a screen content, a virtual reality (VR) picture) and/or any combination thereof (e.g. an augmented reality (AR) picture). The picture source may be any kind of memory or storage storing any of the aforementioned pictures.

In distinction to the pre-processor 18 and the processing performed by the pre-processing unit 18, the picture or picture data 17 may also be referred to as raw picture or raw picture data 17.

Pre-processor 18 is configured to receive the (raw) picture data 17 and to perform pre-processing on the picture data 17 to obtain a pre-processed picture 19 or pre-processed picture data 19. Pre-processing performed by the pre-processor 18 may, e.g., comprise trimming, color format conversion (e.g. from RGB to YCbCr), color correction, or de-noising. It can be understood that the pre-processing unit 18 may be optional component. It is noted that the pre-processing may also employ a neural network (such as in any of FIGS. 1 to 7) which uses the presence indicator signaling.

The video encoder 20 is configured to receive the pre-processed picture data 19 and provide encoded picture data 21.

Communication interface 22 of the source device 12 may be configured to receive the encoded picture data 21 and to transmit the encoded picture data 21 (or any further processed version thereof) over communication channel 13 to another device, e.g. the destination device 14 or any other device, for storage or direct reconstruction.

The destination device 14 comprises a decoder 30 (e.g. a video decoder 30), and may additionally, i.e. optionally, comprise a communication interface or communication unit 28, a post-processor 32 (or post-processing unit 32) and a display device 34.

The communication interface 28 of the destination device 14 is configured receive the encoded picture data 21 (or any further processed version thereof), e.g. directly from the source device 12 or from any other source, e.g. a storage device, e.g. an encoded picture data storage device, and provide the encoded picture data 21 to the decoder 30.

The communication interface 22 and the communication interface 28 may be configured to transmit or receive the encoded picture data 21 or encoded data 13 via a direct communication link between the source device 12 and the destination device 14, e.g. a direct wired or wireless connection, or via any kind of network, e.g. a wired or wireless network or any combination thereof, or any kind of private and public network, or any kind of combination thereof.

The communication interface 22 may be, e.g., configured to package the encoded picture data 21 into an appropriate format, e.g. packets, and/or process the encoded picture data using any kind of transmission encoding or processing for transmission over a communication link or communication network.

The communication interface 28, forming the counterpart of the communication interface 22, may be, e.g., configured to receive the transmitted data and process the transmission data using any kind of corresponding transmission decoding or processing and/or de-packaging to obtain the encoded picture data 21.

Both, communication interface 22 and communication interface 28 may be configured as unidirectional communication interfaces as indicated by the arrow for the communication channel 13 in FIG. 22 pointing from the source device 12 to the destination device 14, or bi-directional communication interfaces, and may be configured, e.g. to send and receive messages, e.g. to set up a connection, to acknowledge and exchange any other information related to the communication link and/or data transmission, e.g. encoded picture data transmission. The decoder 30 is configured to receive the encoded picture data 21 and provide decoded picture data 31 or a decoded picture 31.

The post-processor 32 of destination device 14 is configured to post-process the decoded picture data 31 (also called reconstructed picture data), e.g. the decoded picture 31, to obtain post-processed picture data 33, e.g. a post-processed picture 33. The post-processing performed by the post-processing unit 32 may comprise, e.g. color format conversion (e.g. from YCbCr to RGB), color correction, trimming, or re-sampling, or any other processing, e.g. for preparing the decoded picture data 31 for display, e.g. by display device 34.

The display device 34 of the destination device 14 is configured to receive the post-processed picture data 33 for displaying the picture, e.g. to a user or viewer. The display device 34 may be or comprise any kind of display for representing the reconstructed picture, e.g. an integrated or external display or monitor. The displays may, e.g. comprise liquid crystal displays (LCD), organic light emitting diodes (OLED) displays, plasma displays, projectors, micro LED displays, liquid crystal on silicon (LCoS), digital light processor (DLP) or any kind of other display.

Although FIG. 22 depicts the source device 12 and the destination device 14 as separate devices, embodiments of devices may also comprise both or both functionalities, the source device 12 or corresponding functionality and the destination device 14 or corresponding functionality. In such embodiments the source device 12 or corresponding functionality and the destination device 14 or corresponding functionality may be implemented using the same hardware and/or software or by separate hardware and/or software or any combination thereof.

As will be apparent for the skilled person based on the description, the existence and (exact) split of functionalities of the different units or functionalities within the source device 12 and/or destination device 14 as shown in FIG. 22 may vary depending on the actual device and application.

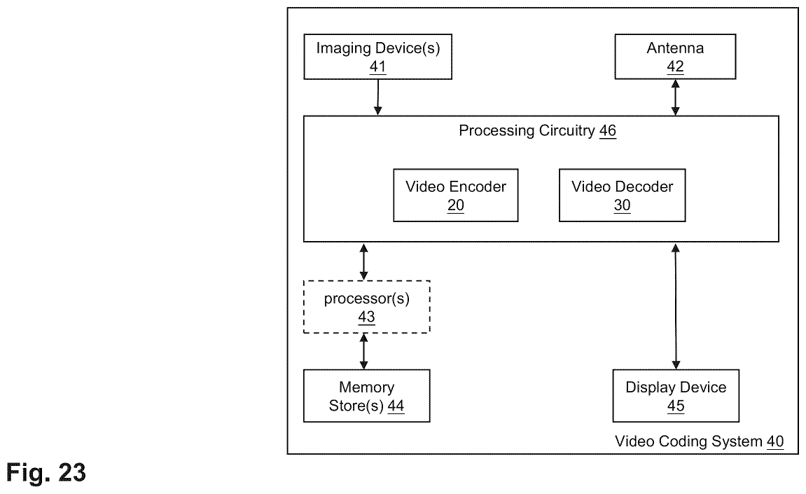

The encoder 20 (e.g. a video encoder 20) or the decoder 30 (e.g. a video decoder 30) or both encoder 20 and decoder 30 may be implemented via processing circuitry, such as one or more microprocessors, digital signal processors (DSPs), application-specific integrated circuits (ASICs), field-programmable gate arrays (FPGAs), discrete logic, hardware, video coding dedicated or any combinations thereof. The encoder 20 may be implemented via processing circuitry 46 to embody the various modules including the neural network or its parts. The decoder 30 may be implemented via processing circuitry 46 to embody any coding system or subsystem described herein. The processing circuitry may be configured to perform the various operations as discussed later. If the techniques are implemented partially in software, a device may store instructions for the software in a suitable, non-transitory computer-readable storage medium and may execute the instructions in hardware using one or more processors to perform the techniques of this disclosure. Either of video encoder 20 and video decoder 30 may be integrated as part of a combined encoder/decoder (CODEC) in a single device, for example, as shown in FIG. 23.

Source device 12 and destination device 14 may comprise any of a wide range of devices, including any kind of handheld or stationary devices, e.g. notebook or laptop computers, mobile phones, smart phones, tablets or tablet computers, cameras, desktop computers, set-top boxes, televisions, display devices, digital media players, video gaming consoles, video streaming devices(such as content services servers or content delivery servers), broadcast receiver device, broadcast transmitter device, or the like and may use no or any kind of operating system. In some cases, the source device 12 and the destination device 14 may be equipped for wireless communication. Thus, the source device 12 and the destination device 14 may be wireless communication devices.

In some cases, video coding system 10 illustrated in FIG. 22 is merely an example and the techniques of the present application may apply to video coding settings (e.g., video encoding or video decoding) that do not necessarily include any data communication between the encoding and decoding devices. In other examples, data is retrieved from a local memory, streamed over a network, or the like. A video encoding device may encode and store data to memory, and/or a video decoding device may retrieve and decode data from memory. In some examples, the encoding and decoding is performed by devices that do not communicate with one another, but simply encode data to memory and/or retrieve and decode data from memory.

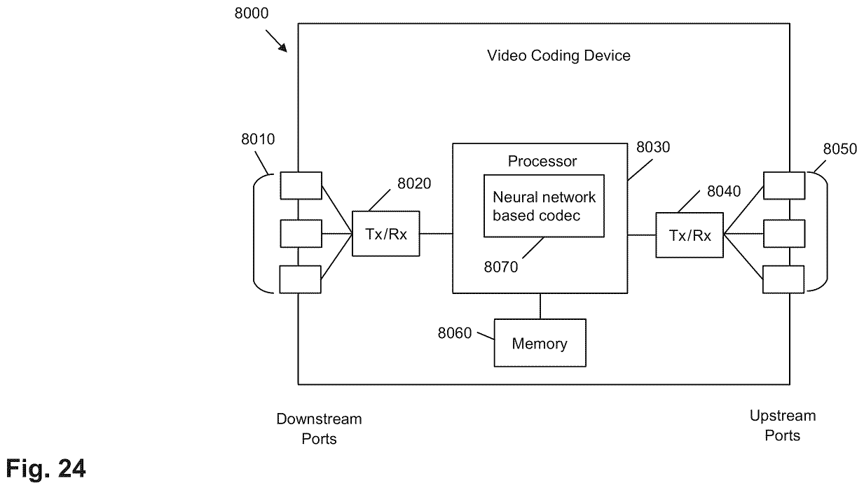

FIG. 24 is a schematic diagram of a video coding device 8000 according to an embodiment of the disclosure. The video coding device 8000 is suitable for implementing the disclosed embodiments as described herein. In an embodiment, the video coding device 8000 may be a decoder such as video decoder 30 of FIG. 22 or an encoder such as video encoder 20 of FIG. 22.

The video coding device 8000 comprises ingress ports 8010 (or input ports 8010) and receiver units (Rx) 8020 for receiving data; a processor, logic unit, or central processing unit (CPU) 8030 to process the data; transmitter units (Tx) 8040 and egress ports 8050 (or output ports 8050) for transmitting the data; and a memory 8060 for storing the data. The video coding device 8000 may also comprise optical-to-electrical (OE) components and electrical-to-optical (EO) components coupled to the ingress ports 8010, the receiver units 8020, the transmitter units 8040, and the egress ports 8050 for egress or ingress of optical or electrical signals.

The processor 8030 is implemented by hardware and software. The processor 8030 may be implemented as one or more CPU chips, cores (e.g., as a multi-core processor), FPGAs, ASICs, and DSPs. The processor 8030 is in communication with the ingress ports 8010, receiver units 8020, transmitter units 8040, egress ports 8050, and memory 8060. The processor 8030 comprises a neural network based codec 8070. The neural network based codec 8070 implements the disclosed embodiments described above. For instance, the neural network based codec 8070 implements, processes, prepares, or provides the various coding operations. The inclusion of the neural network based codec 8070 therefore provides a substantial improvement to the functionality of the video coding device 8000 and effects a transformation of the video coding device 8000 to a different state. Alternatively, the neural network based codec 8070 is implemented as instructions stored in the memory 8060 and executed by the processor 8030.

The memory 8060 may comprise one or more disks, tape drives, and solid-state drives and may be used as an over-flow data storage device, to store programs when such programs are selected for execution, and to store instructions and data that are read during program execution. The memory 8060 may be, for example, volatile and/or non-volatile and may be a read-only memory (ROM), random access memory (RAM), ternary content-addressable memory (TCAM), and/or static random-access memory (SRAM).

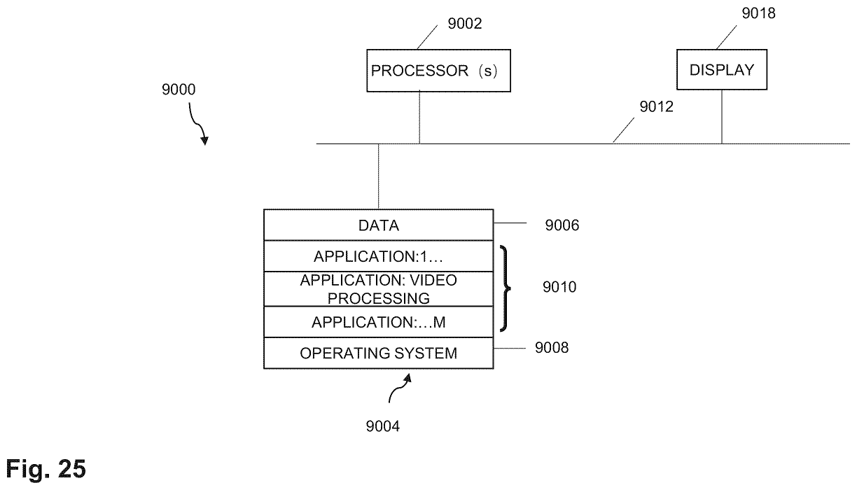

FIG. 25 is a simplified block diagram of an apparatus that may be used as either or both of the source device 12 and the destination device 14 from FIG. 22 according to an exemplary embodiment.

A processor 9002 in the apparatus 9000 can be a central processing unit. Alternatively, the processor 9002 can be any other type of device, or multiple devices, capable of manipulating or processing information now-existing or hereafter developed. Although the disclosed implementations can be practiced with a single processor as shown, e.g., the processor 9002, advantages in speed and efficiency can be achieved using more than one processor.

A memory 9004 in the apparatus 9000 can be a read only memory (ROM) device or a random access memory (RAM) device in an implementation. Any other suitable type of storage device can be used as the memory 9004. The memory 9004 can include code and data 9006 that is accessed by the processor 9002 using a bus 9012. The memory 9004 can further include an operating system 9008 and application programs 9010, the application programs 9010 including at least one program that permits the processor 9002 to perform the methods described here. For example, the application programs 9010 can include applications 1 through N, which further include a video coding application that performs the methods described here.

The apparatus 9000 can also include one or more output devices, such as a display 9018. The display 9018 may be, in one example, a touch sensitive display that combines a display with a touch sensitive element that is operable to sense touch inputs. The display 9018 can be coupled to the processor 9002 via the bus 9012.

Although depicted here as a single bus, the bus 9012 of the apparatus 9000 can be composed of multiple buses. Further, a secondary storage can be directly coupled to the other components of the apparatus 9000 or can be accessed via a network and can comprise a single integrated unit such as a memory card or multiple units such as multiple memory cards. The apparatus 9000 can thus be implemented in a wide variety of configurations.

Although embodiments of the present disclosure have been primarily described based on video coding, it should be noted that embodiments of the coding system 10, encoder 20 and decoder 30 (and correspondingly the system 10) and the other embodiments described herein may also be configured for still picture processing or coding, i.e. the processing or coding of an individual picture independent of any preceding or consecutive picture as in video coding. In general only inter-prediction units 244 (encoder) and 344 (decoder) may not be available in case the picture processing coding is limited to a single picture 17. All other functionalities (also referred to as tools or technologies) of the video encoder 20 and video decoder 30 may equally be used for still picture processing, e.g. residual calculation 204/304, transform 206, quantization 208, inverse quantization 210/310, (inverse) transform 212/312, partitioning 262/362, intra-prediction 254/354, and/or loop filtering 220, 320, and entropy coding 270 and entropy decoding 304.

Embodiments, e.g. of the encoder 20 and the decoder 30, and functions described herein, e.g. with reference to the encoder 20 and the decoder 30, may be implemented in hardware, software, firmware, or any combination thereof. If implemented in software, the functions may be stored on a computer-readable medium or transmitted over communication media as one or more instructions or code and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

By way of example, and not limiting, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transitory media, but are instead directed to non-transitory, tangible storage media. Disk and disc, as used herein, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated hardware and/or software modules configured for encoding and decoding, or incorporated in a combined codec. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a codec hardware unit or provided by a collection of interoperative hardware units, including one or more processors as described above, in conjunction with suitable software and/or firmware.

While operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

Summarizing, methods and apparatuses are provided to approximate a cumulative distribution function (CDF) interval-wise with second order polynomials, while posing constraints on the polynomials within the intervals and/or on the boundary between the intervals. In this manner, a CDF approximation is obtained, which may be used in a variety of applications including entropy encoding and decoding of any source data. The constraints correspond to the characteristics of the CDF to be approximated.

What is claimed is:

1. A method for entropy encoding data into a bitstream, the method comprising:
obtaining a cumulative distribution function (CDF) for at least one interval out of a plurality of intervals, wherein the CDF is obtained based on a function defined in the at least one interval by parameters of a second order polynomial, and wherein the second order polynomial fulfills a set of conditions; and
entropy encoding the data applying a probability model based on the obtained CDF in the at least one interval.

2. The method according to claim 1, wherein the set of conditions includes at least one of:
the second order polynomial within the at least one interval and a polynomial in an adjoining interval provide a monotonically non-decreasing function, or
the second order polynomial has a non-negative derivative within the at least one interval.

3. The method according to claim 1, wherein the function defined by the parameters specifies a predefined CDF with a predefined mean value and a predefined standard deviation.

4. The method according to claim 3, wherein the CDF is obtained by shifting at least one argument of the function.

5. The method according to claim 3, wherein the CDF is obtained by scaling at least one argument of the function.

6. A method for entropy decoding data from a bitstream, the method comprising:
obtaining a cumulative distribution function (CDF) for at least one interval out of a plurality of predetermined intervals, wherein the CDF is obtained based on a function defined in the at least one interval by parameters of a second order polynomial, and three second order polynomial fulfills a set of conditions; and
entropy decoding the data applying a probability model based on the obtained CDF in the at least one interval.

7. The method according to claim 6, wherein the set of conditions includes at least one of:
the second order polynomial within the at least one interval and a polynomial in an adjoining interval provide a monotonically non-decreasing function, or
the second order polynomial has a non-negative derivative within the at least one interval.

8. The method according to claim 6, wherein the function defined by the parameters specifies a predefined CDF with a predefined mean value and a predefined standard deviation.

9. The method according to claim 8, wherein the CDF is obtained by shifting at least one argument of the function.

10. The method according to claim 8, wherein the CDF is obtained by scaling at least one argument of the function.

11. The method according to claim 6, wherein the entropy decoding is an arithmetic decoding.

12. The method according to claim 6, wherein the function within one or more intervals out of the plurality of intervals is defined by a linear polynomial.

13. The method according to claim 6, wherein the function within a last interval out of the plurality of intervals is defined by a linear polynomial.

14. The method according to claim 6, wherein the function approximates a predefined CDF having a predefined mean and a predefined standard deviation, the function is point-symmetric with respect to the predefined mean, and the function is defined in intervals including values higher than the predefined mean.

15. The method according to claim 6, wherein a look-up table (LUT) provides the parameters for each interval.

16. The method according to claim 6, wherein the obtained CDF represents a CDF of a Gaussian distribution.

17. The method according to claim 6, wherein the parameters are in a fixed-point representation having a predetermined precision.

18. The method according to claim 17, wherein in the obtaining of the CDF, intermediate results are adapted to the predetermined precision according to a set of rules.

19. The method according to claim 17, wherein for a value x=s−μ−0.5 within the at least one interval, where s represents a symbol to be encoded, and y is a mean of the CDF,
the CDF is obtained for x smaller than zero by
$$CDF ( x ) = M - ( {a}_{i} {v}^{2} + {b}_{i} v + {c}_{i} ) + s$$
wherein aᵢ, bᵢ and cᵢ are the parameters of the second order polynomial within the at least one interval,
$$v = \frac{- x}{{σ}_{left} + ϵ}$$
scales the value x by a standard deviation σ_{left} of the CDF for x smaller than zero and a predetermined parameter ϵ>0, and M is a multiplication factor, which is related to a predetermined precision 1/M, M is defined by M=total−sₘₐₓ−1, where total is related to a number of bits used in entropy encoding and sₘₐₓ is a maximal value of the symbol to be encoded; and
the CDF is obtained for x greater than zero by
$$CDF ( x ) = {a}_{i} {v}^{2} + {b}_{i} v + {c}_{i} + s$$
wherein aᵢ, bᵢ and cᵢ are the parameters of the second order polynomial within the at least one interval,
$$v = \frac{x}{{σ}_{right} + ϵ}$$
scales the value x by the standard deviation σ_{left} of the CDF for x greater than zero and the predetermined parameter ϵ>0.

20. A method for obtaining a set of parameters specifying a cumulative distribution function (CDF) for entropy encoding, the method comprising:
for an interval within a plurality of predetermined intervals:
obtaining a subset of the set of parameters defining a second order polynomial within the interval, the second order polynomial approximating the CDF, wherein the second order polynomial fulfills a set of conditions.

21. The computer program stored on a non-transitory medium and including code instructions, which, when executed on one or more processors, cause the one or more processors to execute steps of the method according to claim 1.

22. An apparatus for entropy encoding data into a bitstream, the apparatus comprising:
processing circuitry configured to:
obtain a cumulative distribution function (CDF) for at least one interval out of a plurality of predetermined intervals, wherein the CDF is obtained based on a function defined in the at least one interval by parameters of a second order polynomial, and the second order polynomial fulfills a set of conditions;
entropy encode the data applying a probability model based on the obtained CDF in the at least one interval.

23. An apparatus for entropy decoding data from a bitstream, the apparatus comprising:
processing circuitry configured to:
obtain a cumulative distribution function (CDF) for at least one interval out of a plurality of predetermined intervals, wherein the CDF is obtained based on a function defined in the at least one interval by parameters of a second order polynomial, and the second order polynomial fulfills a set of conditions; and
entropy decode the data applying a probability model based on the obtained CDF in the at least one interval.

24. An apparatus for obtaining a set of parameters specifying a cumulative distribution function (CDF) for entropy encoding, the apparatus comprising
processing circuitry configured to:
for an interval within a plurality of predetermined intervals:
obtain a subset of the set of parameters defining a second order polynomial within the interval, the second order polynomial approximating the CDF, wherein the polynomial fulfills a set conditions.
